(19) United States
(12) Patent Application Publication
(10) Pub. No.: US 2026/0063668 A1
(43) Pub. Date: Mar. 5, 2026

(54) OPTOELECTRONIC PROBE CARDS, OPTOELECTRONIC TESTERS, AND RELATED METHODS

(71) Applicant: FormFactor, Inc., Livermore, CA (US)

(72) Inventors: Quan Yuan, Dublin, CA (US); Daniel Rishavy, Austin, TX (US); Michael E. Simmons, Colton, OR (US); Divya Pratap, Beaverton, OR (US)

(21) Appl. No.: 19/291,445

(22) Filed: Aug. 5, 2025

Related U.S. Application Data
(60) Provisional application No. 63/690,994, filed on Sep. 5, 2024.

(51) Int. Cl. G01R 1/07; G01R 1/073

(52) U.S. Cl. CPC G01R 1/071; G01R 1/07342

(57) ABSTRACT

Optoelectronic probe cards, optoelectronic testers, and related methods. The optoelectronic probe cards are configured for optical and electrical communication with a device under test (DUT) on a device substrate that includes a plurality of DUTs and includes an optical probe assembly and an electrical probe assembly. The optical probe assembly includes a plurality of lensed optical probes configured for non-contact optical communication with at least one optoelectronic device of the DUT. The electrical probe assembly includes a plurality of electrical probes configured for electrical communication with the DUT via electrical contact between the plurality of electrical probes and a plurality of contact pads of the DUT. The optoelectronic testers include a chuck, the optoelectronic probe card, an optical signal generation and analysis assembly, and an electrical signal generation and analysis assembly. The methods include actively and/or passively aligning components of the optoelectronic probe card with corresponding components of the DUT.

### RELATED APPLICATION

This application claims priority to U.S. Provisional Patent Application No. 63/690,994, which was filed on Sep. 5, 2024, and the complete disclosure of which is hereby incorporated by reference.

### FIELD OF THE DISCLOSURE

The present disclosure relates generally to optoelectronic probe cards, optoelectronic testers, and related methods.

### BACKGROUND OF THE DISCLOSURE

Applications for optoelectronic devices have expanded significantly in recent years and are expected to increase substantially in the coming years. Optoelectronic devices include both electrical input/output terminals (e.g., contact pads) and optical input/output terminals (e.g., waveguides and/or grating couplers). It may be desirable to test the operation, functionality, and/or performance of optoelectronic devices. Such testing may require providing electrical signals to the contact pads, receiving electrical signals from the contact pads, providing optical signals to the optical input/output terminals, and/or receiving optical signals from the optical input/output terminals. Historically, such testing has been performed utilizing individual electrical probes with associated manipulators and individual optical probes with associated manipulators. Such a configuration, while effective in certain circumstances, may be slow and/or may not be amenable to testing in a high-volume manufacturing environment. Thus, there exists a need for optoelectronic probe cards, for optoelectronic testers that include the optoelectronic probe cards, and for related methods.

### SUMMARY OF THE DISCLOSURE

Optoelectronic probe cards, optoelectronic testers, and related methods. The optoelectronic probe cards are configured for optical and electrical communication with a device under test (DUT) on a device substrate that includes a plurality of DUTs and includes an optical probe assembly and an electrical probe assembly. The optical probe assembly may include a plurality of lensed optical probes configured for non-contact optical communication with at least one optoelectronic device of the DUT. Each lensed optical probe of the plurality of lensed optical probes may define a fixed orientation relative to each other lensed optical probe of the plurality of lensed optical probes. The electrical probe assembly may include a plurality of electrical probes configured for electrical communication with the DUT via electrical contact between the plurality of electrical probes and a plurality of contact pads of the DUT. Each electrical probe of the plurality of electrical probes may define a fixed orientation relative to each other electrical probe of the plurality of electrical probes.

The optoelectronic testers are configured to optically and electrically test a device under test (DUT) on a device substrate that includes a plurality of DUTs and includes a chuck, the optoelectronic probe card, an optical signal generation and analysis assembly, and an electrical signal generation and analysis assembly. The chuck may define a support surface configured to support the device substrate. The optical signal generation and analysis assembly may be configured to provide an optical test signal to the DUT via the optical probe assembly of the optoelectronic probe card and/or receive an optical resultant signal from the DUT via the optical probe assembly. The electrical signal generation and analysis assembly may be configured to provide an electrical test signal to the DUT via the electrical probe assembly of the optoelectronic probe card and/or to receive an electrical resultant signal from the DUT via the electrical probe assembly.

The methods include methods of testing a device under test (DUT), which is on a device substrate that includes a plurality of DUTs, utilizing an optoelectronic probe card. The optoelectronic probe card includes an optical probe assembly that includes a plurality of lensed optical probes and an electrical probe assembly that includes a plurality of electrical probes. In some examples, the methods may include actively aligning the plurality of electrical probes with a plurality of corresponding contact pads of the DUT and actively aligning the plurality of lensed optical probes with at least one optoelectronic device of the DUT. In some examples, the plurality of lensed optical probes and the plurality of electrical probes may define a fixed relative orientation therebetween. In such examples, the methods may include actively aligning the plurality of electrical probes with a plurality of corresponding contact pads of the DUT and passively aligning the plurality of lensed optical probes with at least one optoelectronic device of the DUT.

Alternatively, and in such examples, the methods may include actively aligning the plurality of lensed optical probes with at least one optoelectronic device of the DUT and passively aligning the plurality of electrical probes with a plurality of corresponding contact pads of the DUT.

### BRIEF DESCRIPTION OF THE DRAWINGS

FIG. 1 is a schematic illustration of examples of optoelectronic testers that include optoelectronic probe cards, according to the present disclosure.

FIG. 2 is a plot illustrating an example of sensitivity of optical coupling, between an optoelectronic device and a lensed optical probe, to relative alignment between the optoelectronic device and the lensed optical probe.

FIG. 3 is a schematic top isometric view illustrating examples of an optoelectronic probe card according to the present disclosure.

FIG. 4 is a schematic top isometric view illustrating examples of another optoelectronic probe card according to the present disclosure.

FIG. 5 is a partially transparent top isometric view of a region of the optoelectronic probe card of FIG. 4.

FIG. 6 is a bottom isometric view of a region of the optoelectronic probe card of FIGS. 4-5.

FIG. 7 is a schematic top isometric view illustrating examples of another optoelectronic probe card according to the present disclosure.

FIG. 8 is a schematic bottom isometric view of the optoelectronic probe card of FIG. 7.

FIG. 9 is a schematic cross-sectional view illustrating examples of another optoelectronic probe card according to the present disclosure.

FIG. 10 is a schematic side view illustrating an example of a lensed optical probe configured to optically couple to a sidewall surface of a device under test, according to the present disclosure.

FIG. 11 is a flowchart illustrating examples of methods of testing a device under test utilizing an optoelectronic probe card, according to the present disclosure.

FIG. 12 is an illustration of a configuration for optoelectronic testers during the methods of FIG. 11.

FIG. 13 is an illustration of a configuration for optoelectronic testers during the methods of FIG. 11.

FIG. 14 is an illustration of a configuration for optoelectronic testers during the methods of FIG. 11.

FIG. 15 is an illustration of a configuration for optoelectronic testers during the methods of FIG. 11.

### DETAILED DESCRIPTION AND BEST MODE OF THE DISCLOSURE

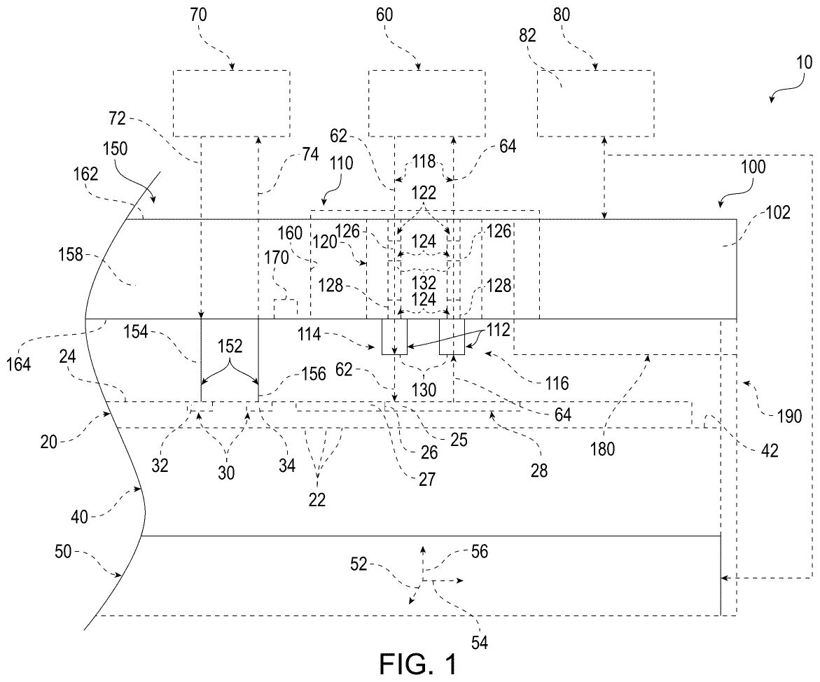

FIGS. 1 and 3-15 provide examples of optoelectronic testers 10, of optoelectronic probe cards 100, and/or of methods 200, according to the present disclosure. Elements that serve a similar, or at least substantially similar, purpose are labeled with like numbers in each of FIGS. 1-15, and these elements may not be discussed in detail herein with reference to each of FIGS. 1-15. Similarly, all elements may not be labeled in each of FIGS. 1-15, but reference numerals associated therewith may be utilized herein for consistency. Elements, components, and/or features that are discussed herein with reference to one or more of FIGS. 1-15 may be included in and/or utilized with any of FIGS. 1-15 without departing from the scope of the present disclosure.

In general, elements that are likely to be included in a particular embodiment are illustrated in solid lines, while elements that may be optional are illustrated in dashed lines. However, elements that are shown in solid lines may not be essential to all embodiments and, in some embodiments, may be omitted without departing from the scope of the present disclosure.

FIG. 1 is a schematic illustration of examples of optoelectronic testers 10 that include optoelectronic probe cards 100, according to the present disclosure. As illustrated in FIG. 1, optoelectronic testers 10 are configured to test a device under test (DUT) 22 on a device substrate 20 that includes a plurality of DUTs 22. DUT 22 includes at least one optoelectronic device 28 and a plurality of contact pads 30.

Optoelectronic testers 10 include a chuck 40 that defines a support surface 42, which is configured to support device substrate 20. Examples of chuck 40 include a thermal chuck, an electrically shielded chuck, and/or a vacuum chuck.

Optoelectronic testers 10 also include optoelectronic probe card 100, which includes an optical probe assembly 110 and an electrical probe assembly 150. Optical probe assembly 110 includes a plurality of lensed optical probes 112, and electrical probe assembly 150 includes a plurality of electrical probes 152.

Optoelectronic testers 10 further include an optical signal generation and analysis assembly 60 and an electrical signal generation and analysis assembly 70. Optical signal generation and analysis assembly 60 is configured to provide an optical test signal 62 to DUT 22, or to the at least one optoelectronic device 28 thereof, via optical probe assembly 110 of optoelectronic probe card 100 and/or to receive an optical resultant signal 64 from the DUT via the optical probe assembly. Electrical signal generation and analysis assembly 70 is configured to provide an electrical test signal 72 to DUT 22, or to one or more contact pads 30 thereof, via electrical probe assembly 150 of optoelectronic probe card 100 and/or to receive an electrical resultant signal 74 from the DUT via the electrical probe assembly. Examples of optical signal generation and analysis assembly 60 include a light source, a laser light source, an electromagnetic radiation source, a light detector, a laser light detector, an electromagnetic radiation detector, a photodetector, and/or a charge-coupled device. Examples of electrical signal generation and analysis assembly 70 include an electric current source, an electric voltage source, a direct current source, an alternating current source, a high frequency current source, a function generator, an electric current detector, an electric voltage detector, an electric signal analyzer, and/or an impedance analyzer.

In some examples, and as illustrated in dashed lines in FIG. 1, optoelectronic testers 10 may include a chuck stage 50. Chuck stage 50 may be configured to translate, to operatively translate, to rotate, and/or to operatively rotate support surface 42 relative to optoelectronic probe card 100, such as to permit and/or facilitate at least partial alignment between DUT 22 and the optoelectronic probe card. This may include translation and/or rotation within a plane that is parallel to support surface 42, such as may be along and/or about a first dimension 52 and/or a second dimension 54 that extend parallel to the plane. Additionally or alternatively, this may include translation and/or rotation that is perpendicular to the plane, such as may be along and/or about a third dimension 56.

In some examples, and as also illustrated in dashed lines in FIG. 1, optoelectronic tester 10 may include a controller 80. Controller 80 may include and/or be any suitable structure, device, and/or devices that may be adapted, configured, designed, constructed, and/or programmed to perform the functions discussed herein. As examples, controller 80 may include one or more of an electronic controller, a dedicated controller, a special-purpose controller, a personal computer, a special-purpose computer, a display device, a logic device, a memory device, and/or a memory device having computer-readable storage media 82.

The computer-readable storage media, when present, also may be referred to herein as non-transitory computer readable storage media. This non-transitory computer readable storage media may include, define, house, and/or store computer-executable instructions, programs, and/or code; and these computer-executable instructions may direct optoelectronic tester 10 and/or controller 80 thereof to perform any suitable portion, or subset, of methods 200. Examples of such non-transitory computer-readable storage media include CD-ROMs, disks, hard drives, flash memory, etc. As used herein, storage, or memory, devices and/or media having computer-executable instructions, as well as computer-implemented methods and other methods according to the present disclosure, are considered to be within the scope of subject matter deemed patentable in accordance with Section 101 of Title 35 of the United States Code.

During operation of optoelectronic testers 10, and as discussed in more detail herein, electrical probes 152 of electrical probe assembly 150 may be aligned, or simultaneously may be aligned, with contact pads 30 of DUT 22. In addition, lensed optical probes 112 of optical probe assembly 110 may be aligned, or simultaneously may be aligned, with optoelectronic device 28. Thus, optoelectronic testers 10 and/or optoelectronic probe cards 100 permit and/or facilitate both electrical testing of DUT 22 via electrical probes 152 and optical testing of DUT 22 via lensed optical probes 112. The optoelectronic testers 10 and/or optoelectronic probe cards 100 further may be configured to permit and/or facilitate concurrent, or at least partially concurrent, electrical testing of DUT 22 via electrical probes 152 and optical testing of DUT 22 via lensed optical probes 112.

Optoelectronic probe cards 100 and/or optoelectronic testers 10 that include the optoelectronic probe cards 100 may provide a number of benefits over conventional optoelectronic testers. As an example, and as discussed in more detail herein, all electrical probes 152 concurrently and/or simultaneously may be aligned with contact pads 30, thereby decreasing testing time when compared to conventional optoelectronic testers that utilize individual conventional manipulators to individually align individual conventional electrical probes. As another example, and as discussed in more detail herein, all lensed optical probes 112 concurrently and/or simultaneously may be aligned with optoelectronic device 28, further decreasing testing time when compared to conventional optoelectronic testers that utilize individual conventional manipulators to individually align individual conventional optical probes.

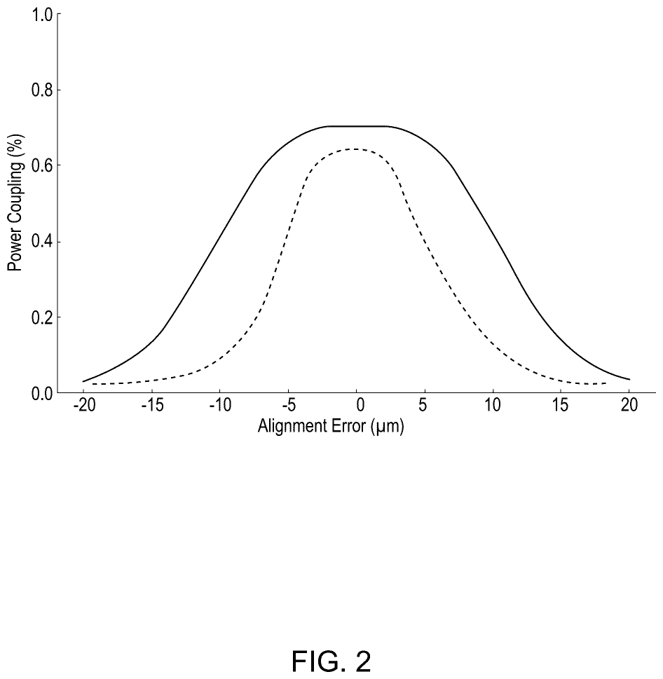

As yet another example, inclusion of lensed optical probes 112 within optoelectronic probe cards 100 may provide a benefit over conventional optical probes, such as polished optical fibers, that do not include lenses. In particular, and as illustrated in FIG. 2, a coupling efficiency, or power coupling percentage, is less sensitive to alignment error for lensed optical probes 112, as illustrated in solid lines, when compared to conventional optical probes, as illustrated in dashed lines.

As another example, and as discussed in more detail herein, optoelectronic testers 10 and/or optoelectronic probe cards 100 may provide individual, separate, and/or distinct mechanisms for alignment between electrical probes 152 and contact pads 30 versus alignment between lensed optical probes 112 and optoelectronic device 28. In general, an accuracy and/or precision of alignment needed for electrical contact between electrical probes 152 and contact pads 30 is on the order of 10's of micrometers, while an accuracy and/or precision of alignment needed for optical coupling between lensed optical probes 112 and optoelectronic device 28 is on the order of a few micrometers. As such, optoelectronic testers 10 and/or optoelectronic probe cards 100 may permit and/or facilitate selection of individual mechanisms for alignment that provide a desired level of accuracy and/or precision for electrical probes 152 when compared to lensed optical probes 112, thereby ensuring the ability to accomplish alignment while minimizing overall system costs.

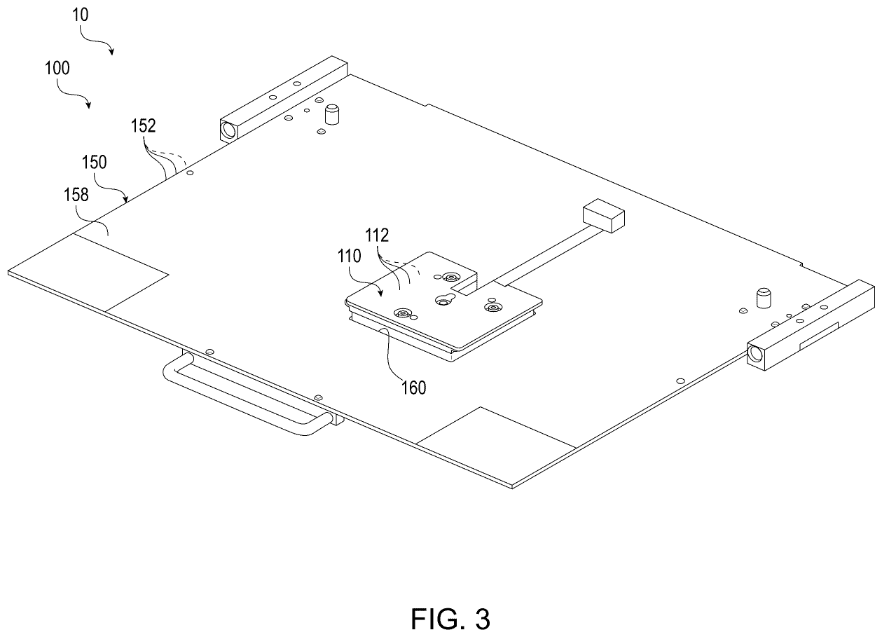

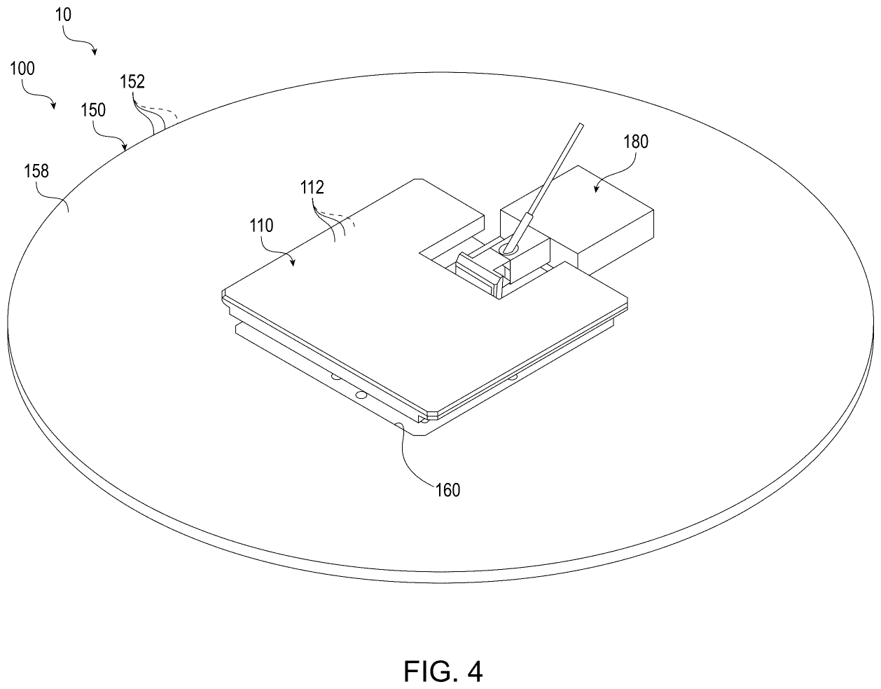

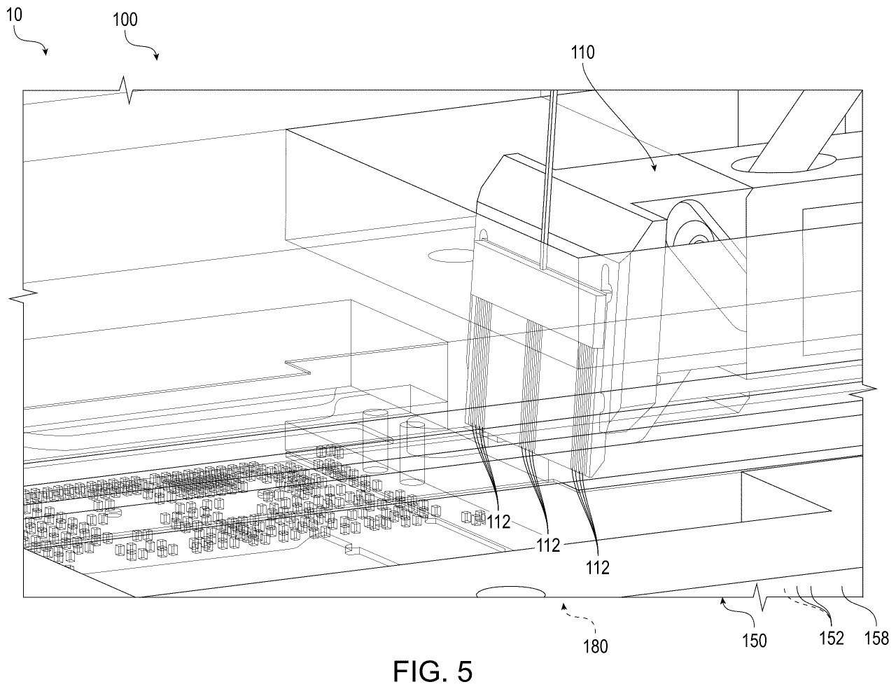

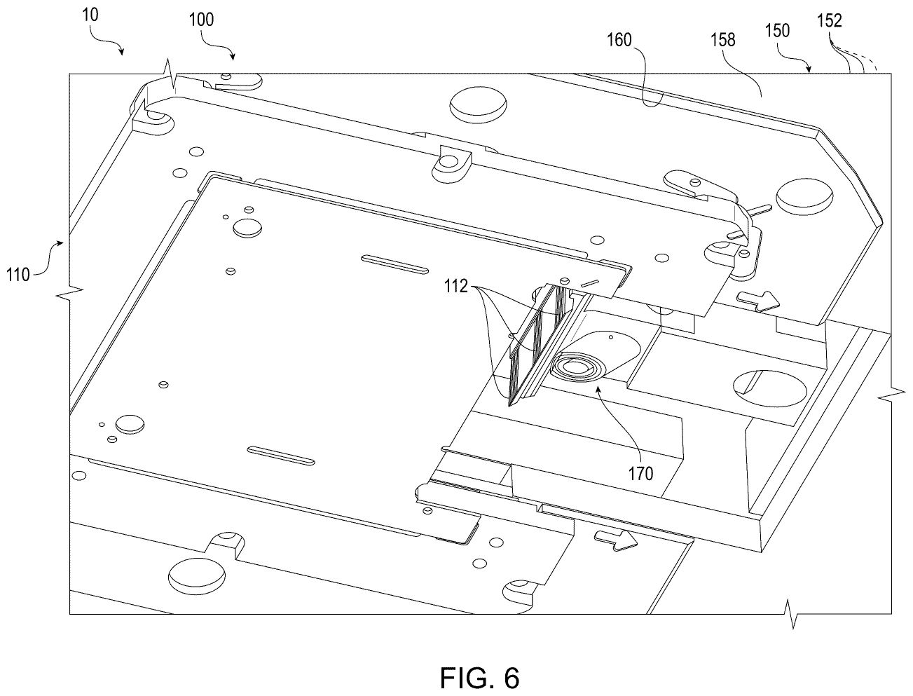

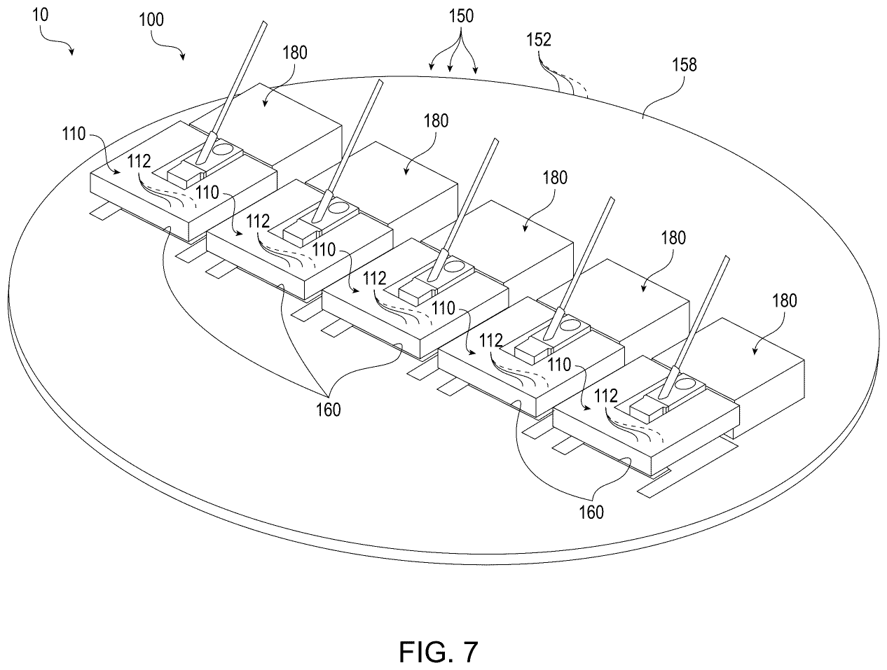

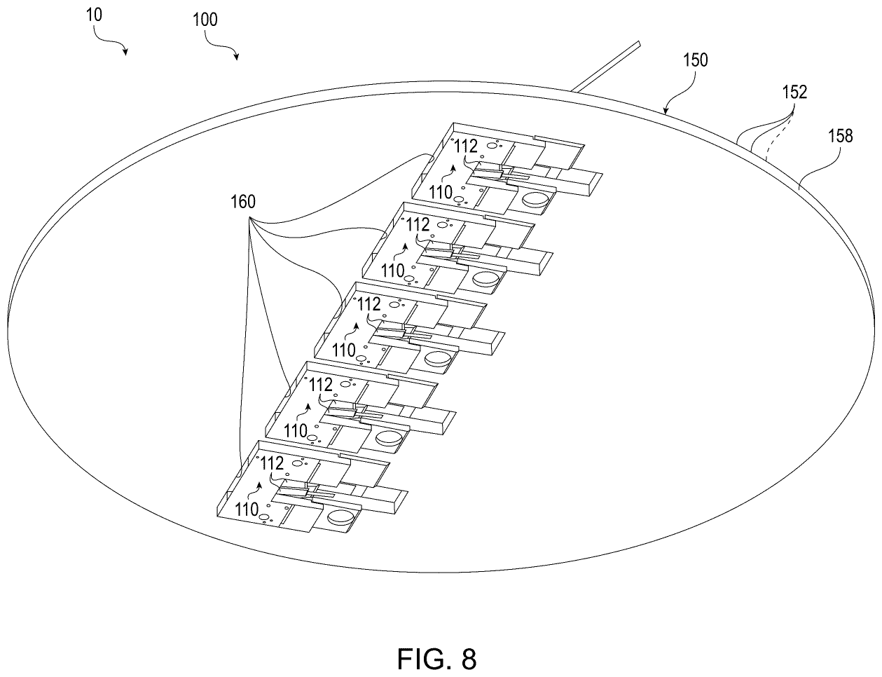

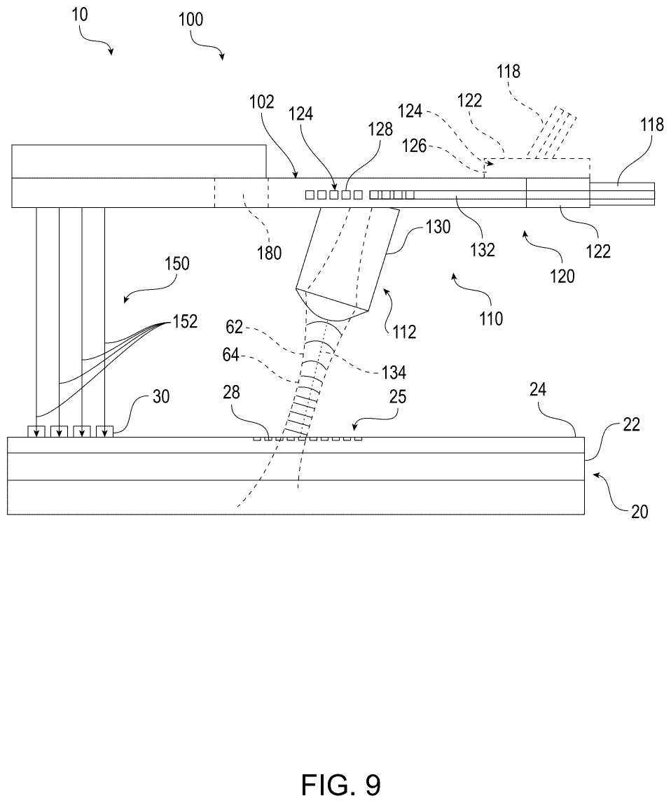

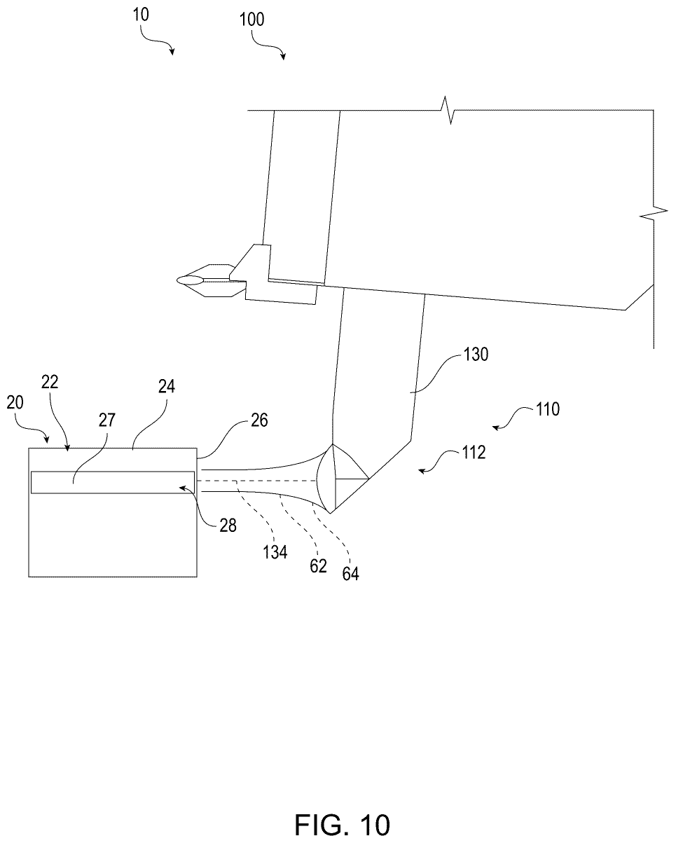

FIG. 3 is a schematic top isometric view of examples of an optoelectronic probe card 100 according to the present disclosure. FIG. 4 is a schematic top isometric view of examples of another optoelectronic probe card 100 according to the present disclosure, FIG. 5 is a partially transparent view of a region of the optoelectronic probe card of FIG. 4, and FIG. 6 is a bottom isometric view of optoelectronic testers 10 and/or optoelectronic probe cards 100 that permit and/or facilitate both electrical testing of DUT 22 via electrical probes 152 and optical testing of DUT 22 via lensed optical probes 112. FIG. 7 is a schematic top isometric view of examples of another optoelectronic probe card 100 according to the present disclosure, and FIG. 8 is a schematic bottom isometric view of the optoelectronic probe card of FIG. 7. FIG. 9 is a schematic cross-sectional view of examples of another optoelectronic probe card 100 according to the present disclosure, and FIG. 10 is a schematic side view illustrating an example of a lensed optical probe 112 configured to optically couple to a sidewall surface 26 of a DUT 22, according to the present disclosure.

Optoelectronic probe cards 100 that are illustrated in FIGS. 3-10 may include and/or be more detailed and/or less schematic illustrations of optoelectronic probe cards 100 that are illustrated in FIG. 1. Thus, any structure, function, and/or feature of optoelectronic probe cards 100 of FIGS. 3-10 may be included in and/or utilized with optoelectronic testers 10 and/or optoelectronic probe cards 100 of FIG. 1 without departing from the scope of the present disclosure. Similarly, any structure, function, and/or feature of optoelectronic testers 10 and/or of optoelectronic probe cards 100 of FIG. 1 may be included in and/or utilized with optoelectronic probe cards 100 of FIGS. 3-10 without departing from the scope of the present disclosure.

Returning to FIG. 1, and with general reference to FIGS. 3-10, optoelectronic probe cards 100 include optical probe assembly 110 that includes a plurality of lensed optical probes 112. Lensed optical probes 112 are configured for non-contact optical communication with at least one optoelectronic device 28 of DUT 22, as illustrated in FIGS. 1 and 9-10.

Optoelectronic probe cards 100 also include electrical probe assembly 150 that includes a plurality of electrical probes 152. Electrical probes 152 are configured for electrical communication with DUT 22, such as via contact, or electrical contact, between electrical probes 152 and contact pads 30 of DUT 22. Optical probe assembly 110 and electrical probe assembly 150 may be positioned and/or oriented, relative to one another, such that lensed optical probes 112 are positioned for non-contact optical communication with optoelectronic device 28 when and/or while electrical probes 152 are positioned for electrical contact and/or electrical communication with contact pads 30, as illustrated in FIGS. 1 and 9.

Optical probe assembly 110 may include any suitable structure that includes lensed optical probes 112 and/or that may be adapted, configured, designed, and/or constructed for non-contact and/or optical communication with optoelectronic devices 28. As illustrated in FIG. 1, optical probe assembly 110 may be configured to convey at least one optical test signal 62 to optoelectronic device 28, such as via a corresponding signal-emitting lensed optical probe 114 of lensed optical probes 112. In some such examples, signal-emitting lensed optical probe 114 may be configured to emit the at least one optical test signal 62 and/or to focus the at least one optical test signal on optoelectronic device 28.

Additionally or alternatively, optical probe assembly 110 may be configured to receive at least one optical resultant signal 64 from optoelectronic device 28, such as via a corresponding signal-receiving lensed optical probe 116 of lensed optical probes 112. In some such examples, signal-receiving lensed optical probe 116 may be configured to collect the at least one optical resultant signal 64.

The signal-emitting lensed optical probe may differ from the signal-receiving lensed optical probe. Alternatively, the signal-emitting lensed optical probe and the signal-receiving lensed optical probe may include and/or be the same lensed optical probe 112.

It is within the scope of the present disclosure that lensed optical probes 112 may be configured to couple, or to optically couple, with DUT 22 and/or with optoelectronic device 28 thereof, such as to permit, perform, and/or establish optical communication with the optoelectronic device. This may be accomplished in any suitable manner. As an example, lensed optical probes 112 may be configured to optically couple with an upper surface 24 of DUT 22, as illustrated in FIGS. 1 and 9. In such examples, optoelectronic device 28 may include a grating coupler 25, which may be configured to permit and/or to facilitate the optical coupling. Additionally or alternatively, lensed optical probes 112 may be configured to optically couple with a sidewall surface 26 of DUT 22, as illustrated in FIGS. 1 and 10. In such examples, optoelectronic device 28 may include a waveguide 27, which may be configured to receive optical test signal 62 and/or to emit optical resultant signal 64.

In contrast to conventional optoelectronic testers, which generally include individual conventional manipulators to individually move individual conventional optical probes, lensed optical probes 112 of optical probe assembly 110 may define a fixed, or an at least substantially fixed, relative orientation therebetween. Stated differently, each lensed optical probe may define a fixed and/or a predetermined orientation relative to each other lensed optical probe. Stated still differently, the orientation of each lensed optical probe relative to each other lensed optical probe may be based, at least in part, on a configuration of optoelectronic device 28, such as on a location and/or orientation of grating couplers and/or waveguides of the optoelectronic device.

Optical probe assembly 110 and/or lensed optical probes 112 thereof may include any suitable structure for non-contact optical communication with the at least one optoelectronic device of the DUT. As an example, and as illustrated in FIGS. 1 and 9, each lensed optical probe 112 may include and/or may be in optical communication with a corresponding optical fiber 118. Such a configuration may permit and/or facilitate transfer of optical test signal 62 and/or optical resultant signal 64 between optical signal generation and analysis assembly 60 and optical probe assembly 110, as illustrated in FIG. 1. As another example, and with reference to FIGS. 1 and 9-10, each lensed optical probe 112 may include a corresponding probe lens 130. Probe lens 130 may be configured to focus optical test signal 62 onto DUT 22 and/or to collect optical resultant signal 64 from the DUT. As additional examples, and as discussed in more detail herein, each lensed optical probe 112 may include a corresponding waveguide 132 and/or a corresponding grating coupler 124.

Electrical probe assembly 150 may include any suitable structure that includes electrical probes 152 and/or that is configured for electrical communication with DUT 22, such as via electrical contact between electrical probes 152 and corresponding contact pads 30 of the DUT. Similarly, electrical probes 152 may include and/or be any suitable structure that may electrically communicate with and/or electrically contact the contact pads of the DUT.

As illustrated in FIG. 1, electrical probe assembly 150 may be configured to convey at least one electrical test signal 72 to at least one signal-receiving contact pad 32 via a corresponding signal-emitting electrical probe 154. Additionally or alternatively, electrical probe assembly 150 may be configured to receive at least one electrical resultant signal 74 from at least one signal-emitting contact pad 34 via a corresponding signal-receiving electrical probe 156. The signal-emitting electrical probe may differ from the signal-receiving electrical probe. Alternatively, the signal-emitting electrical probe and the signal-receiving electrical probe may include and/or be the same electrical probe 152.

In contrast to conventional optoelectronic testers, which generally include individual conventional manipulators to individually move individual conventional electrical probes, electrical probes 152 of electrical probe assembly 150 may define a fixed, or an at least substantially fixed, relative orientation therebetween. Stated differently, each electrical probe may define a fixed and/or a predetermined orientation relative to each other electrical probe. Stated still differently, the orientation of each electrical probe relative to each other electrical probe may be based, at least in part, on and/or may correspond to a relative orientation of contact pads 30 of DUT 22.

Electrical probes 152 may include any suitable structure for electrical communication with the DUT via electrical contact with the plurality of contact pads of the DUT. Examples of electrical probes 152 include resilient electrical probes, resiliently biased electrical probes, and/or electrically conductive electrical probes. In some examples, electrical probes 152 may be configured to directly contact the contact pads of the DUT.

In some examples of optoelectronic probe card 100, and as illustrated in FIGS. 1 and 3-8, electrical probe assembly 150 may include and/or be an electrical probe card 158. In such examples, electrical probes 152 may be operatively attached to and/or may extend from the electrical probe card. Also in such examples, electrical probe card 158 may form and/or define an opening 160, which also may be referred to herein as an aperture 160, as illustrated in FIGS. 1, 3-4, and 6-8. Optical probe assembly 110 may be positioned at least partially within and/or may extend at least partially through opening 160. Stated differently, and as illustrated in FIG. 1, optical probe assembly 110 may extend, via opening 160, at least partially, or even completely, between a device substrate-opposed side 162 and a device substrate-facing side 164 of electrical probe card 158. Device substrate-opposed side 162 may face away from device substrate 20 and/or from support surface 42, while device substrate-facing side 164 may face toward the device substrate and/or toward the support surface. Stated still differently, opening 160 may at least partially, or even fully, surround optical probe assembly 110 and/or lensed optical probes 112 thereof, at least when viewed from a direction that is parallel to a surface normal direction of device substrate-opposed side 162 and/or of device substrate-facing side 164.

It is within the scope of the present disclosure that optical probe assembly 110 may be operatively, directly, and/or rigidly attached to electrical probe card 158. This attachment may be such that the plurality of lensed optical probes and the plurality of electrical probes may define a fixed, or at least substantially fixed, relative orientation therebetween. Stated differently, optoelectronic probe card 100 may not be configured for relative motion between lensed optical probes 112 and electrical probes 152 and/or optoelectronic probe card 100 may be configured to maintain the fixed, or at least substantially fixed, relative orientation between the lensed optical probes and the electrical probes during operative use of the optoelectronic probe card.

Such a configuration may permit and/or facilitate concurrent electrical contact between electrical probes 152 and contact pads 30 and optical communication between lensed optical probes 112 and optoelectronic device 28. In addition, such a configuration may permit a single structure, such as chuck stage 50, to facilitate, or to facilitate all, relative motion between DUT 22 and the optoelectronic probe card. Thus, such a configuration may be relatively less expensive to implement and/or faster to utilize when compared to other examples of optoelectronic probe cards 100 that are disclosed herein. In addition, utilization of lensed optical probes 112, which include probe lenses 130, may permit and/or facilitate sufficient optical communication between the lensed optical probes and the optoelectronic device to permit certain types of optical testing despite some misalignment between the lensed optical probes and the optoelectronic device. However, such a configuration may, in some examples, provide lower quality optical coupling between the lensed optical probes and the optoelectronic device when compared to other examples of optoelectronic probe cards 100 that are disclosed herein. This lower quality optical coupling may be insufficient to permit other types of optical testing. In such conditions, other examples of optoelectronic probe cards 100 may be utilized.

As illustrated in dashed lines in FIG. 1 and in solid lines in FIGS. 4 and 7, optoelectronic probe cards 100 may include a probe assembly actuator 180. Probe assembly actuator 180, when present, may be adapted, configured, designed, and/or constructed to selectively produce and/or generate relative motion between lensed optical probes 112 and electrical probes 152. This may be accomplished in any suitable manner. As an example, probe assembly actuator 180 may be configured to operatively translate lensed optical probes 112 relative to electrical probes 152 and/or to operatively translate electrical probes 152 relative to lensed optical probes 112. In a specific example, the probe assembly actuator may operatively attach optical probe assembly 110 and electrical probe assembly 150 to one another. In another specific example, one of the optical probe assembly and the electrical probe assembly may be operatively attached to a support structure 190, as illustrated in FIG. 1, and may define a fixed, or at least substantially fixed, orientation relative to the support structure. In such examples, the other of the optical probe assembly and the electrical probe assembly may be operatively attached to the support structure via the probe assembly actuator. Stated differently, the probe assembly actuator may be configured to operatively translate the other of the optical probe assembly and the electrical probe assembly relative to the support structure. In a specific example, the electrical probe assembly may define the fixed orientation relative to the support structure, and the optical probe assembly may be operatively attached to the support structure via the probe assembly actuator. Examples of the support structure include a platen of the optoelectronic tester and/or a test head of the optoelectronic tester.

It is within the scope of the present disclosure that probe assembly actuator 180 may be configured to produce and/or generate any suitable relative motion between the optical probe assembly and the electrical probe assembly and/or between the lensed optical probes and the electrical probes. As an example, the probe assembly actuator may be configured to selectively generate the relative motion in two dimensions. As another example, the probe assembly actuator may be configured to selectively generate the relative motion within a motion plane that extends parallel, or at least substantially parallel, to support surface 42 of chuck 40, that extends parallel, or at least substantially parallel, to upper surface 24 of device substrate 20, and/or that extends parallel, or at least substantially parallel, to a contact plane within which the electrical probes are configured to contact the contact pads of the DUT. In some examples, the probe assembly actuator also may be configured to selectively generate the relative motion within a third dimension that extends perpendicular, or at least substantially perpendicular, to the two dimensions and/or to the motion plane. Examples of the two dimensions are illustrated in FIG. 1 and indicated at 52 and 54. An example of the third dimension is illustrated in FIG. 1 and indicated at 56.

Probe assembly actuator 180 may include any suitable structure that produces and/or generates the relative motion. Examples of probe assembly actuator 180 include a rack and pinion assembly, a lead screw and nut assembly, a ball screw and nut assembly, a linear actuator, a rotary actuator, a servo motor, a stepper motor, and/or a piezoelectric actuator. In some examples, a resolution and/or a spatial resolution of probe assembly actuator 180 may be greater than a corresponding resolution and/or spatial resolution of chuck stage 50. Additionally or alternatively, and in some such examples, a minimum motion magnitude of probe assembly actuator 180 may be less than a corresponding minimum motion magnitude of chuck stage 50. Such a configuration may permit and/or facilitate positioning of lensed optical probes 112 relative to optoelectronic device 28 with a greater accuracy and/or precision when compared to positioning of electrical probes 152 relative to contact pads 30 of DUT 22.

As illustrated in FIGS. 1 and 9, the optoelectronic probe card may include a card substrate 102, and optical probe assembly 110 and/or electrical probe assembly 150 may be at least partially defined by, on, and/or within the card substrate. Examples of the card substrate include a semiconductor wafer and/or a printed circuit board. In some such examples, lensed optical probes 112 and/or electrical probes 152 may define a fixed, or at least substantially fixed, orientation relative to the card substrate and/or relative to one another. In some such examples, lensed optical probes 112 and/or electrical probes 152 may be operatively attached to and/or may extend from the card substrate.

With continued reference to FIGS. 1 and 9, optoelectronic probe cards 100 may include optical fibers 118 and an optical interface structure 120 that is in optical communication with the optical fibers. Optical interface structure 120 may include a plurality of optical fiber receptacles 122, each of which may be configured to receive a corresponding optical fiber 118, to interface with the corresponding optical fiber, and/or to operatively attach the corresponding optical fiber to card substrate 102. An example of optical fiber receptacles 122 includes V-grooves.

As illustrated in solid lines in FIG. 9, optical fibers 118 may approach and/or interface with card substrate 102 in a direction that is parallel, or at least substantially parallel, to a plane defined by card substrate 102. In such examples, optical interface structure 120 and/or V-grooves thereof may be at least partially defined by and/or within card substrate 102.

Additionally or alternatively, and as illustrated in dashed lines in FIG. 9, optical fibers 118 may approach and/or interface with card substrate 102 at another angle (e.g., a skew angle and/or an angle that is not parallel to the plane defined by the card substrate). In such examples, optical interface structure 120 additionally or alternatively may include a plurality of grating couplers 124 in the form of fiber-interfaced grating couplers 126. Each fiber-interfaced grating coupler 126 may be in optical communication with a corresponding optical fiber 118. Additionally or alternatively, each fiber-interfaced grating coupler 126 may be at least partially, or even completely, defined by, on, and/or within card substrate 102.

With continued reference to FIGS. 1 and 9, optoelectronic probe cards 100 may include a plurality of waveguides 132. Each waveguide may be in optical communication with a corresponding optical fiber 118, such as via optical interface structure 120. Additionally or alternatively, each waveguide 132 may be at least partially, or even completely, defined by, on, and/or within card substrate 102.

As also illustrated, optoelectronic probe cards 100 may include a plurality of grating couplers 124, in the form of a plurality of lens-interfaced grating couplers 128, and a plurality of probe lenses 130. Each waveguide 132 may be in optical communication with a corresponding probe lens 130 via a corresponding lens-interfaced grating coupler 128. Additionally or alternatively, each lens-interfaced grating coupler may be at least partially, or even completely, defined by, on, and/or within card substrate 102.

As illustrated in dashed lines in FIG. 1 and in solid lines in FIG. 6, optoelectronic testers 10 and/or optoelectronic probe cards 100 thereof may include an imaging device 170. Imaging device 170 may be adapted, configured, designed, and/or constructed to collect an optical image of one or more components of optoelectronic tester 10 and/or of device substrate 20. As examples, imaging device 170 may be configured to collect the optical image of DUT 22, of optoelectronic device 28, of contact pads 30, of lensed optical probes 112, and/or of electrical probes 152. In some examples, and as discussed in more detail herein, imaging device 170 and/or the optical image that is collected therewith may be utilized to permit and/or facilitate alignment between electrical probes 152 and contact pads 30 and/or between lensed optical probes 112 and optoelectronic device 28.

It is within the scope of the present disclosure that optoelectronic probe cards 100 may be configured to test, or to simultaneously test, any suitable number of DUTs, may include any suitable number of electrical probes 152, and/or may include any suitable number of lensed optical probes 112. As an example, and as illustrated by the region of the optoelectronic probe card that is illustrated in FIG. 1, optoelectronic probe cards 100 may be configured to optical and electrical communication with a single, or only a single, DUT at a given point in time. However, this is not required of all examples, and it is within the scope of the present disclosure that optoelectronic probe cards 100 may be configured to test, or to simultaneously test, any suitable number of DUTs at a given point in time, including one, two, three, four, five, six, seven, eight, nine, ten, or more than ten DUTs. Stated differently, optoelectronic probe cards 100 may be configured for optical and electrical communication with a plurality of DUTs at a given time.

In a specific example, and as illustrated in FIG. 5, the optoelectronic probe card may include three separate arrays of lensed optical probes 112, each of which may be configured for optical communication with a corresponding DUT. In the example of FIG. 5, the optoelectronic probe card includes probe assembly actuator 180, which is configured to move the three separate arrays of lensed optical probes together and/or as a unit. Such a configuration may, in some examples, permit simultaneous testing of more DUTs when compared to the example that is illustrated in FIG. 3 (which does not include the probe assembly actuator), as inclusion of the probe assembly actuator may improve optical alignment between the lensed optical probes and the corresponding optoelectronic devices and/or may permit each separate array of lensed optical probes to be sufficiently aligned with corresponding optoelectronic devices of corresponding DUTs to permit and/or facilitate optical communication therebetween.

In another specific example, and as illustrated in FIGS. 7-8, the optoelectronic probe card may include a plurality of optical probe assemblies 110 and a corresponding plurality of electrical probe assemblies 150. In such a configuration, each optical probe assembly and each electrical probe assembly may be configured for electrical and optical communication with a corresponding DUT. In some examples, the plurality of electrical probe assemblies may define a fixed, or at least substantially fixed, relative orientation therebetween. In some such examples, the plurality of optical probe assemblies also may define a fixed, or at least substantially fixed, relative orientation therebetween. Alternatively, and as illustrated in FIGS. 7-8, the optoelectronic probe card may include a plurality of probe assembly actuators 180. In such a configuration, each probe assembly actuator may be configured to selectively generate relative motion between a corresponding optical probe assembly and a corresponding electrical probe assembly. Such a configuration may permit and/or facilitate simultaneous testing of additional DUTs and/or may permit each of the lensed optical probes of each optical probe assembly of the plurality of optical probe assemblies to be sufficiently aligned with corresponding optoelectronic devices of corresponding DUTs to permit and/or facilitate optical communication therebetween.

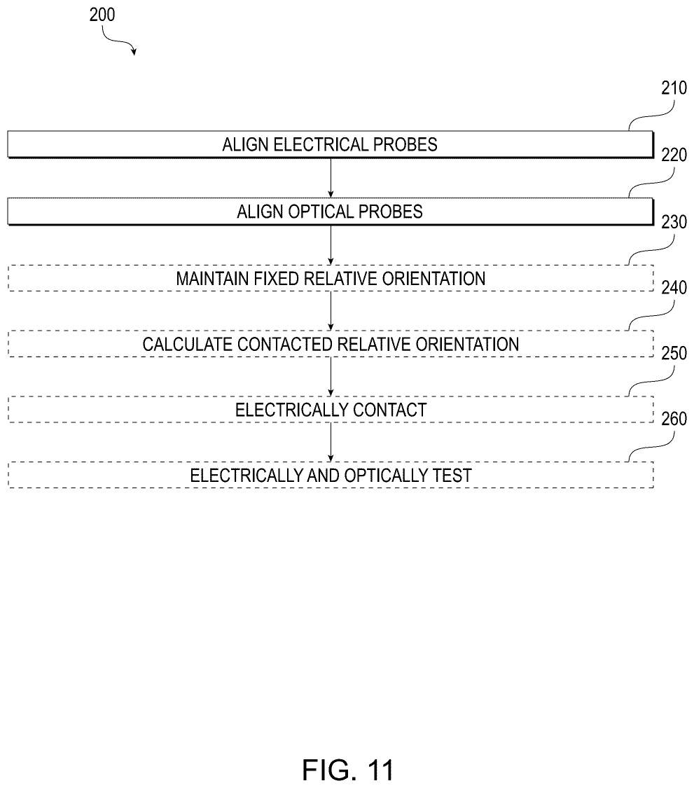

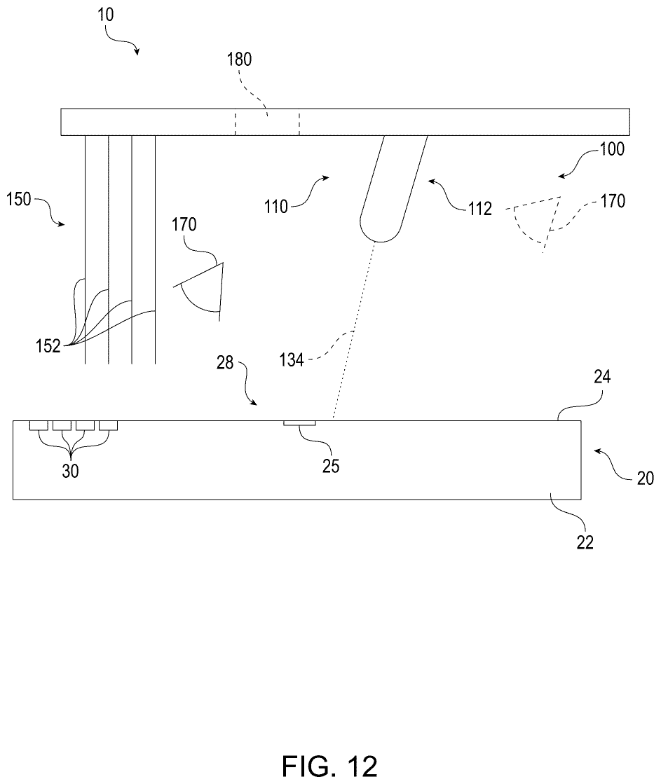

FIG. 11 is a flowchart illustrating examples of methods 200 of testing a device under test (DUT) utilizing an optoelectronic probe card, according to the present disclosure, while FIGS. 12-15 illustrate examples of configurations for optoelectronic testers during various steps of methods 200. In the examples of FIGS. 12-15, the optoelectronic probe card is configured for surface coupling with the DUT; however, this is not required to all examples, and it is within the scope of the present disclosure that methods 200 may be utilized with optoelectronic probe cards that are configured for other coupling mechanisms, such as for side wall coupling with the DUT, as is illustrated in FIGS. 1 and 10. The DUT may be on a device substrate that includes a plurality of DUTs. The optoelectronic probe card may include an optical probe assembly that includes a plurality of lensed optical probes and an electrical probe assembly that includes a plurality of electrical probes. Examples of the device under test are disclosed herein with reference to DUT 22. Examples of the optoelectronic probe card and/or components thereof are disclosed herein with reference to optoelectronic probe card 100.

Methods 200 include aligning electrical probes at 210 and aligning optical probes at 220. Methods 200 also may include maintaining a fixed relative orientation at 230, calculating a contacted relative orientation at 240, electrically contacting at 250, and/or electrically and optically testing at 260.

Aligning electrical probes at 210 may include aligning the plurality of electrical probes with a plurality of corresponding contact pads of the DUT. This may be accomplished in any suitable manner. As an example, the aligning at 210 may include moving the plurality of electrical probes relative to the plurality of corresponding contact pads. As another example, the aligning at 210 may include moving the plurality of corresponding contact pads relative to the plurality of electrical probes.

In some examples, the aligning at 210 may include actively aligning the plurality of electrical probes with the plurality of corresponding contact pads. This may include viewing the plurality of electrical probes and/or viewing the plurality of corresponding contact pads, such as utilizing an imaging device, to permit and/or facilitate the actively aligning. Additionally or alternatively, the actively aligning may include selectively controlling and/or regulating the relative orientation between the plurality of electrical probes and the plurality of corresponding contact pads based, at least in part, on an observed relative orientation therebetween.

In some examples, the aligning at 210 may include passively aligning the plurality of electrical probes with the plurality of corresponding contact pads. This may include passively aligning the plurality of electrical probes with the plurality of corresponding contact pads responsive to alignment between two or more other structures. As an example, the passively aligning may include actively aligning another structure of the optoelectronic probe card, such as the plurality of lensed optical probes, with a corresponding structure of the DUT, such as the optoelectronic device. In such an example, passive alignment between the plurality of electrical probes and the plurality of corresponding contact pads may be responsive to the active alignment between the other structure of the optoelectronic probe card with the other structure of the DUT.

The aligning at 210 may be performed with any suitable timing and/or sequence during methods 200. As examples, the aligning at 210 may be performed prior to, subsequent to, at least partially concurrently with, and/or responsive to the aligning at 220, the maintaining at 230, the calculating at 240, and/or the electrically contacting at 250. As another example, the aligning at 210 may be performed prior to the electrically and optically testing at 260.

Aligning optical probes at 220 may include aligning the plurality of lensed optical probes with an optoelectronic device of the DUT. This may include aligning the plurality of lensed optical probes with one or more optical communication structures of the optoelectronic device, such as a waveguide and/or a grating coupler. This may be accomplished in any suitable manner. As an example, the aligning at 220 may include moving the plurality of lensed optical probes relative to the optoelectronic device. As another example, the aligning at 220 may include moving the optoelectronic device relative to the plurality of lensed optical probes. As yet another example, the aligning at 220 may include establishing optical coupling between the plurality of lensed optical probes and the optoelectronic device.

In some examples, the aligning at 220 may include actively aligning the plurality of lensed optical probes with the optoelectronic device. This may include viewing the plurality of lensed optical probes and/or viewing the optoelectronic device, such as utilizing the imaging device, to permit and/or facilitate the actively aligning. Additionally or alternatively, the actively aligning may include selectively controlling and/or regulating the relative orientation between the plurality of lensed optical probes and the optoelectronic device based, at least in part, on an observed relative orientation therebetween and/or based, at least in part, on a quality of optical coupling therebetween. Additionally or alternatively, the actively aligning may include determining a relative orientation between the plurality of lensed optical probes and the optoelectronic device at which optical coupling therebetween is maximized and/or provides greater than a threshold optical coupling efficiency magnitude. This may include conveying an electromagnetic signal between the plurality of lensed optical probes and the optoelectronic device while moving one of the plurality of lensed optical probes and the optoelectronic device relative to the other of the plurality of lensed optical probes and the optoelectronic device.

In some examples, the aligning at 220 may include passively aligning the plurality of lensed optical probes with the optoelectronic device. This may include passively aligning the plurality of lensed optical probes with the optoelectronic device responsive to alignment between two or more other structures. As an example, the passively aligning may include actively aligning another structure of the optoelectronic probe card, such as the plurality of electrical probes, with a corresponding structure of the DUT, such as the plurality of corresponding contact pads. In such an example, passive alignment between the plurality of lensed optical probes and the optoelectronic device may be responsive to the active alignment between the other structure of the optoelectronic probe card with the other structure of the DUT.

The aligning at 220 may be performed with any suitable timing and/or sequence during methods 200. As examples, the aligning at 220 may be performed prior to, subsequent to, at least partially concurrently with, and/or responsive to the aligning at 210, the maintaining at 230, the calculating at 240, and/or the electrically contacting at 250. As another example, the aligning at 220 may be performed prior to the electrically and optically testing at 260.

As used herein, the phrase “actively aligning” refers to an alignment process between two or more actively aligned components in which relative motion between the two or more actively aligned components is controlled and/or regulated based, at least in part, on a measured relative orientation between the two or more actively aligned components and/or based, at least in part, on at least one parameter that is representative of alignment between the two or more actively aligned components. Examples of the at least one parameter that is representative of alignment between the two or more actively aligned components include an optical image of each component, an optical image of both components, the presence or absence of communication between the two or more actively aligned components, and/or a quality of communication between the two or more actively aligned components.

As used herein, the phrase “passively aligning” refers to an alignment process between two or more passively aligned components in which relative motion between the two or more passively aligned components is not controlled and/or regulated based on a measured relative orientation between the two or more passively aligned components. Stated differently, the phrase “passively aligning” refers to an alignment process in which alignment between the two or more passively aligned components is responsive to, or a result of, active alignment between the two or more actively aligned components, which differ from the two or more passively aligned components.

Maintaining the fixed relative orientation at 230 may include maintaining a fixed relative orientation among the plurality of lensed optical probes, among the plurality of electrical probes, and/or between the plurality of lensed optical probes and the plurality of electrical probes during one or more other steps of methods 200. As examples, the maintaining at 230 may include maintaining the fixed relative orientation during the aligning at 210, during the aligning at 220, during the calculating at 230, during the electrically contacting at 250, and/or during the electrically and optically testing at 260.

Calculating the contacted relative orientation at 240 may include calculating a contacted relative orientation between the plurality of lensed optical probes and the optoelectronic device. Examples of the contacted relative orientation are discussed in more detail herein.

Electrically contacting at 250 may include electrically contacting the plurality of electrical probes to the plurality of corresponding contact pads. This may include establishing direct physical contact between the plurality of electrical probes and the plurality of corresponding contact pads while maintaining a spaced-apart relationship between the plurality of lensed optical probes and the optoelectronic device. Additionally or alternatively, this may include moving the plurality of electrical probes and the plurality of corresponding contact pads relative to one another to, or such that they define, the contacted relative orientation.

Electrically and optically testing at 260 may include simultaneously optically testing the DUT and electrically testing the DUT. The testing at 260 may be performed in any suitable manner. As an example, the testing at 260 may include providing at least one optical test signal to the DUT utilizing at least one lensed optical probe of the plurality of lensed optical probes and/or receiving at least one optical resultant signal from the DUT utilizing at least one lensed optical probe of the plurality of lensed optical probes. As another example, the testing at 260 may include providing at least one electrical test signal to the DUT utilizing at least one electrical probe of the plurality of electrical probes and/or receiving at least one electrical resultant signal from the DUT utilizing at least one electrical probe of the plurality of electrical probes.

In a first example of methods 200, the aligning at 210 may include actively aligning the plurality of electrical probes with the plurality of corresponding contact pads. Also in the first example, the aligning at 220 may include passively aligning the plurality of lensed optical probes with at least one optoelectronic device of the DUT.

The actively aligning the plurality of electrical probes at 210 may include moving the plurality of electrical probes relative to the plurality of corresponding contact pads and/or moving the plurality of corresponding contact pads relative to the plurality of electrical probes. Additionally or alternatively, the actively aligning the plurality of electrical probes at 210 may include performing the electrically contacting at 250 to electrically contact the plurality of electrical probes to the plurality of corresponding contact pads. This may be accomplished in any suitable manner. As an example, the actively aligning the plurality of electrical probes at 210 may include optically viewing the plurality of electrical probes and/or the plurality of corresponding contact pads, such as to permit and/or to facilitate the actively aligning.

The passively aligning the plurality of lensed optical probes at 220 may be responsive to the actively aligning the plurality of electrical probes at 210. As an example, a relative orientation between the plurality of electrical probes and the plurality of lensed optical probes may correspond to a relative orientation between the plurality of contact pads and the optoelectronic device. As such, active alignment between the plurality of electrical probes and the plurality of corresponding contact pads may produce and/or generate passive alignment between the plurality of lensed optical probes and the optoelectronic device.

The first example of methods 200 may be performed utilizing optoelectronic probe card 100, such as is illustrated in FIGS. 1 and 3, in which optical probe assembly 110 is rigidly and/or fixedly attached to electrical probe assembly 150. Stated differently, and while not required of all examples, the first example of methods 200 may be performed utilizing an optoelectronic probe card that is configured to maintain a fixed, or at least substantially fixed, relative orientation between the plurality of electrical probes and the plurality of lensed optical probes. Additionally or alternatively, the first example of methods 200 may include performing the maintaining at 230 during the aligning at 210, during the aligning at 220, and/or during all steps of methods 200.

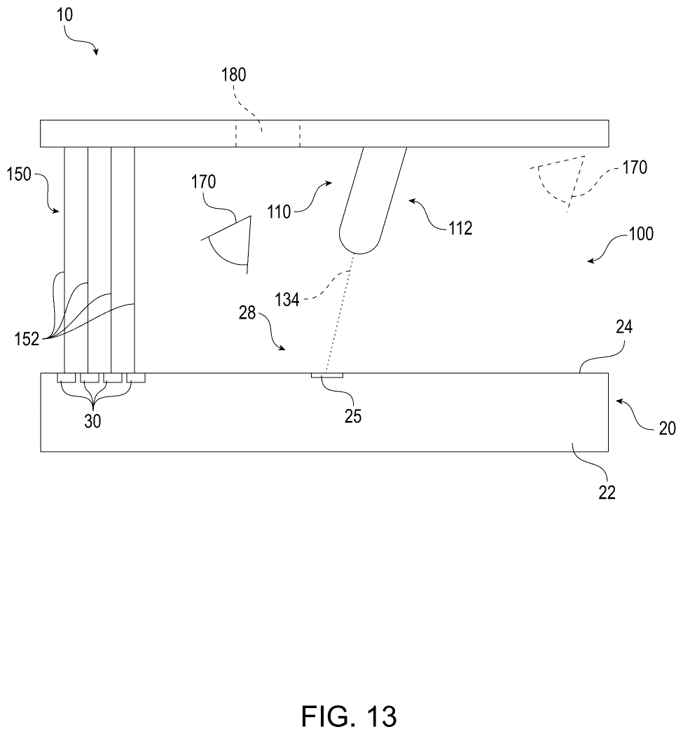

The first example of methods 200 is illustrated by FIGS. 12-13. As illustrated in FIG. 12, electrical probes 152 of electrical probe assembly 150 initially may be misaligned with corresponding contact pads 30 of DUT 22. Similarly, and as also illustrated in FIG. 12, lensed optical probes 112 of optical probe assembly 110 initially may be misaligned with optoelectronic device 28, such as with a grating coupler 25 of the optoelectronic device.

Subsequently, a relative orientation between electrical probes 152 and corresponding contact pads 30 may be observed, such as via imaging device 170 that is illustrated in solid lines, to transition optoelectronic tester 10 to the configuration that is illustrated in FIG. 13. In the first example, and as discussed, alignment between electrical probes 152 and corresponding contact pads 30 may be actively established during the aligning at 210. Concurrently, alignment between lensed optical probes 112 and optoelectronic device 28 may be passively established during the aligning at 220.

In a second example of methods 200, the aligning at 210 may include passively aligning the plurality of electrical probes with the plurality of corresponding contact pads. Also in the second example, the aligning at 220 may include actively aligning the plurality of lensed optical probes with at least one optoelectronic device of the DUT.

The passively aligning the plurality of electrical probes at 210 may be responsive to the actively aligning the plurality of lensed optical probes. As an example, a relative orientation between the plurality of electrical probes and the plurality of lensed optical probes may correspond to a relative orientation between the plurality of contact pads and the optoelectronic device. As such, active alignment between the plurality of lensed optical probes and at least one optoelectronic device may produce and/or generate passive alignment between the plurality of electrical probes and the plurality of corresponding contact pads.

The actively aligning the plurality of lensed optical probes at 220 may include moving the plurality of lensed optical probes relative to the at least one optoelectronic device and/or moving the at least one optoelectronic device relative to the plurality of lensed optical probes. In some examples, the actively aligning the plurality of lensed optical probes at 220 may include determining and/or establishing a relative orientation between the plurality of lensed optical probes and the at least one optoelectronic device that provides at least a threshold optical coupling efficiency between the plurality of lensed optical probes and the at least one optoelectronic device. Additionally or alternatively, the actively aligning the plurality of lensed optical probes at 220 may include establishing the optical coupling between the plurality of lensed optical probes and the at least one optoelectronic device.

This may be accomplished in any suitable manner. As an example, the establishing the relative orientation may include scanning the plurality of lensed optical probes and the at least one optoelectronic device relative to one another in two, in at least two, or three dimensions to determine the relative orientation that provides at least the threshold optical coupling efficiency.

It is within the scope of the present disclosure that the actively aligning the plurality of lensed optical probes at 220 may be performed while the plurality of electrical probes is spaced apart from the plurality of corresponding contact pads. Stated differently, the actively aligning the plurality of lensed optical probes at 220 may be performed while the plurality of electrical probes is out of contact with the plurality of corresponding contact pads. Stated still differently, the passively aligning the plurality of electrical probes may include passively aligning the plurality of electrical probes without contacting the plurality of electrical probes to the plurality of corresponding contact pads. Such a configuration may permit and/or facilitate performing the scanning during the actively aligning the plurality of lensed optical probes without scratching and/or damaging the plurality of contact pads and/or without damaging the plurality of electrical probes, such as may be due to contact between the plurality of electrical probes and the plurality of contact pads during relative motion therebetween.

Subsequent to performing the actively aligning the plurality of lensed optical probes at 220, the second example of methods 200 also may include performing the electrically contacting at 250 to electrically contact the plurality of electrical probes with the plurality of corresponding contact pads. This may be accomplished in any suitable manner. As an example, the actively aligning the plurality of lensed optical probes at 220 may include establishing an aligned relative orientation between the plurality of lensed optical probes and the at least one optoelectronic device. In the aligned orientation, a corresponding optical axis of each lensed optical probe of the plurality of lensed optical probes may be incident upon a corresponding region of the at least one optoelectronic device and/or may define a corresponding aligned optical path length between each lensed optical probe and the corresponding region of the at least one optoelectronic device.

In such a configuration, the electrically contacting at 250 may include establishing the contacted relative orientation between the plurality of lensed optical probes and the at least one optoelectronic device. In the contacted relative orientation, the corresponding optical axis of each lensed optical probe is incident upon the corresponding region of the at least one optoelectronic device. Additionally or alternatively, and in the contacted relative orientation, the corresponding optical axis defines a corresponding contacted optical path length that is greater than zero and/or that is less than the corresponding aligned optical path length. Additionally or alternatively, and in the contacted relative orientation, the plurality of electrical probes is in electrical contact with the plurality of corresponding contact pads.

The second example of methods 200 also may include performing the calculating at 240 to determine the contacted relative orientation. This may be accomplished in any suitable manner. As an example, the calculating at 240 may include calculating and/or determining the contacted relative orientation based, at least in part, on the aligned relative orientation and/or on a predetermined, known, and/or fixed relative orientation between the plurality of lensed optical probes and the plurality of electrical probes.

The second example of methods 200 may be performed utilizing optoelectronic probe card 100, such as is illustrated in FIGS. 1 and 9, in which optical probe assembly 110 and electrical probe assembly 150 both are at least partially defined by card substrate 102. Stated differently, and while not required of all examples, the second example of methods 200 may be performed utilizing an optoelectronic probe card that is configured to maintain a fixed, or at least substantially fixed, relative orientation between the plurality of electrical probes and the plurality of lensed optical probes. Additionally or alternatively, the second example of methods 200 may include performing the maintaining at 230 during the aligning at 210, during the aligning at 220, and/or during all steps of methods 200.

The second example of methods 200 is illustrated by FIGS. 12-14. As illustrated in FIG. 12, and similar to the first example of methods 200, electrical probes 152 of electrical probe assembly 150 initially may be misaligned with corresponding contact pads 30 of DUT 22. Similarly, and as also illustrated in FIG. 12, lensed optical probes 112 of optical probe assembly 110 initially may be misaligned with optoelectronic device 28, such as with a grating coupler 25 of the optoelectronic device.

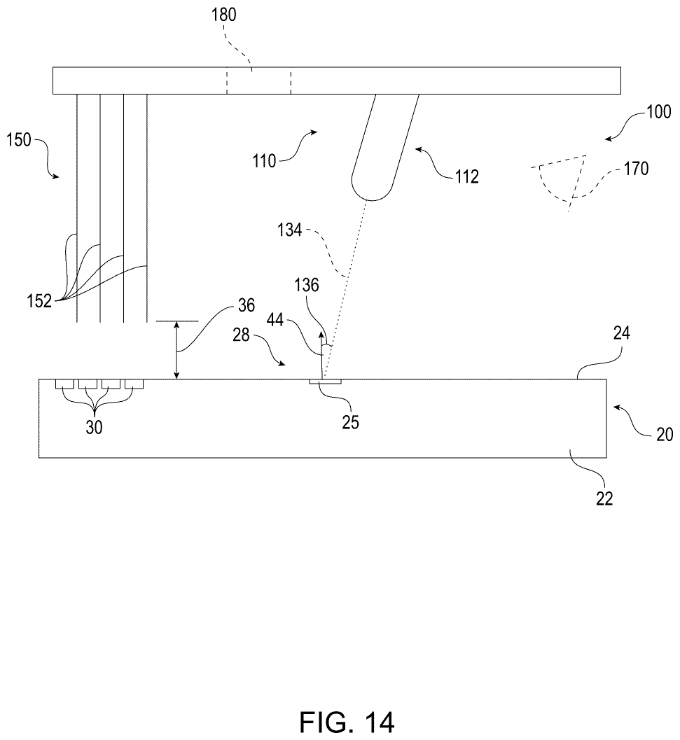

Subsequently, and as illustrated in FIG. 14, lensed optical probe 112 of optical probe assembly 110 may be actively aligned with a corresponding region of optoelectronic device 28, as discussed herein with reference to the actively aligning at 220. In the specific example of FIG. 14, an optical axis 134 of lensed optical probe 112 is actively aligned with a grating coupler 25 of optoelectronic device 28.

The calculating at 240 then may be utilized to determine the contacted relative orientation, and optoelectronic probe card 100 and/or device substrate 20 then may be moved to establish the contacted relative orientation, as illustrated in FIG. 13. In the contacted relative orientation that is illustrated in FIG. 13, electrical probes 152 electrically contact corresponding contact pads 30 of DUT 22 and lensed optical probe 112 is optically aligned with grating coupler 25 of the DUT.

The calculating at 240 may be accomplished in any suitable manner. As an example, and with reference to FIG. 14, a vertical distance 36 between electrical probes 152 and contact pads 30 may be known, measured, observed, and/or determined, such as via visual observation of the distance, measurement of the distance, and/or establishing physical contact between the electrical probes and upper surface 24 of the device substrate followed by separation of the electrical probes from the upper surface of the device substrate by vertical distance 36. Vertical distance 36 may be measured and/or determined along a surface normal direction 44 of device substrate 20 and/or of support surface 42. In addition, an angle of incidence 136 between optical path 134 of lensed optical probe 112 and surface normal direction 44 also may be known, measured, observed, and/or determined, such as via visual observation of the angle of incidence and/or via design and/or construction specifications of optical probe assembly 110. In such a configuration, the contacted relative orientation may be determined utilizing simple trigonometry.

As a specific example, and with continued reference to FIG. 14, the contacted relative orientation may be defined as a relative orientation in which optoelectronic probe card 100 is moved to the left relative to device substrate 20 (or device substrate 20 is moved to the right relative to optoelectronic probe card 100) by a distance that is equal to (vertical distance 36)*tan(angle of incidence 136) and in which the optoelectronic probe card and the device substrate are moved toward one another by a distance that is equal to vertical distance 36. In circumstances in which overdrive between electrical probes 152 and contact pads 30 is desired, an overdrive distance may be added to vertical distance 36 both for the calculation of the left/right relative motion between the optoelectronic probe card and the substrate and for the motion of the optoelectronic probe card and the device substrate toward one another.

In a third example of methods 200, the aligning at 210 may include actively aligning the plurality of electrical probes with the plurality of corresponding contact pads. Also in the third example, the aligning at 220 may include actively aligning the plurality of lensed optical probes with at least one optoelectronic device of the DUT.

The actively aligning the plurality of electrical probes at 210 may include moving the plurality of electrical probes relative to the plurality of corresponding contact pads and/or moving the plurality of corresponding contact pads relative to the plurality of electrical probes. In a specific example, the actively aligning the plurality of electrical probes at 210 may include moving the plurality of corresponding contact pads relative to the plurality of electrical probes and/or relative to the plurality of lensed optical probes. The moving may be performed utilizing a chuck that defines a support surface that supports the device substrate.

The actively aligning the plurality of electrical probes at 210 may include performing the electrically contacting at 250 to electrically contact the plurality of electrical probes to the plurality of corresponding contact pads. This may be accomplished in any suitable manner. As an example, the actively aligning the plurality of electrical probes at 210 may include optically viewing the plurality of electrical probes and/or the plurality of corresponding contact pads, such as to permit and/or to facilitate the actively aligning. The actively aligning the plurality of electrical probes with the plurality of corresponding contact pads at 210 may be performed prior to the actively aligning the plurality of lensed optical probes with the at least one optoelectronic device at 220. This may include establishing the electrical contact between the plurality of electrical probes and the plurality of corresponding contact pads prior to performing the aligning at 220. Stated differently, the aligning at 220 may be performed while the plurality of electrical probes is in electrical contact with the plurality of corresponding contact pads. The actively aligning at 210 is illustrated by FIGS. 12-13 and may be at least substantially similar to the actively aligning at 210 that is performed during the first example of methods 200, which is discussed in more detail herein.

The actively aligning the plurality of lensed optical probes at 220 may include moving the plurality of lensed optical probes relative to the at least one optoelectronic device and/or moving the at least one optoelectronic device relative to the plurality of lensed optical probes. In a specific example, the actively aligning at 220 may include moving the plurality of lensed optical probes relative to the at least one optoelectronic device and also relative to the plurality of electrical probes. The moving may be performed utilizing a probe assembly actuator of the optical probe assembly, examples of which are disclosed herein with reference to probe assembly actuator 180.

In some examples, the actively aligning the plurality of lensed optical probes at 220 may include determining and/or establishing a relative orientation between the plurality of lensed optical probes and the at least one optoelectronic device that provides at least a threshold optical coupling efficiency between the plurality of lensed optical probes and the at least one optoelectronic device. Additionally or alternatively, the actively aligning the plurality of lensed optical probes at 220 may include establishing the optical coupling between the plurality of lensed optical probes and the at least one optoelectronic device.

This may be accomplished in any suitable manner. As an example, the establishing the relative orientation may include scanning the plurality of lensed optical probes and the at least one optoelectronic device relative to one another in two, in at least two, or in three dimensions to determine the relative orientation that provides at least the threshold optical coupling efficiency.

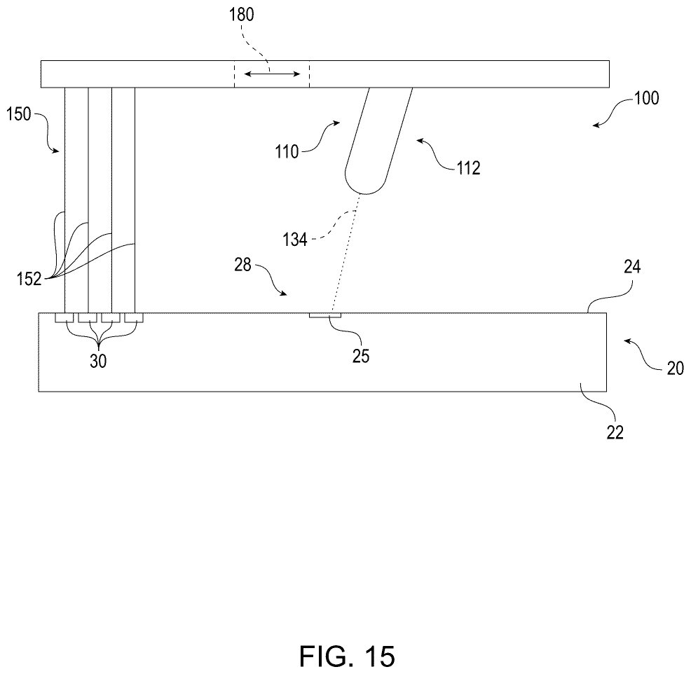

The actively aligning at 220 is illustrated by the transition from the configuration that is illustrated in FIG. 13 to the configuration that is illustrated in FIG. 15. More specifically, and as discussed, the configuration that is illustrated in FIG. 13 may be established via active alignment between electrical probes 152 and contact pads 30 of DUT 22, such as via performing the actively aligning at 210. During the actively aligning at 210, lensed optical probes 112 of optical probe assembly 110 may be passively aligned with corresponding regions, such as grating couplers 25, of optoelectronic device 28. However, this passive alignment may be insufficient to produce the threshold optical coupling efficiency. Thus, and as illustrated in FIG. 15, probe assembly actuator 180 may be utilized to move lensed optical probes 112 relative to grating couplers 25 to produce and/or establish the threshold coupling efficiency therebetween. In such examples, probe assembly actuator 180 also may move lensed optical probes 112 relative to electrical probes 152, as illustrated.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently. It is also within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entities in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” may mean A alone, B alone, C alone, A and B together, A and C together, B and C together, A, B, and C together, and optionally any of the above in combination with at least one other entity.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase, “for example,” the phrase, “as an example,” and/or simply the term “example,” when used with reference to one or more components, features, details, structures, embodiments, and/or methods according to the present disclosure, are intended to convey that the described component, feature, detail, structure, embodiment, and/or method is an illustrative, non-exclusive example of components, features, details, structures, embodiments, and/or methods according to the present disclosure. Thus, the described component, feature, detail, structure, embodiment, and/or method is not intended to be limiting, required, or exclusive/exhaustive; and other components, features, details, structures, embodiments, and/or methods, including structurally and/or functionally similar and/or equivalent components, features, details, structures, embodiments, and/or methods, are also within the scope of the present disclosure.

As used herein, “at least substantially,” when modifying a degree or relationship, may include not only the recited “substantial” degree or relationship, but also the full extent of the recited degree or relationship. A substantial amount of a recited degree or relationship may include at least 75% of the recited degree or relationship. For example, an object that is at least substantially formed from a material includes objects for which at least 75% of the objects are formed from the material and also includes objects that are completely formed from the material. As another example, a first length that is at least substantially as long as a second length includes first lengths that are within 75% of the second length and also includes first lengths that are as long as the second length.

Illustrative, non-exclusive examples of optoelectronic probe cards, optoelectronic testers, and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.
A1. An optoelectronic probe card for optical and electrical communication with a device under test (DUT) on a device substrate that includes a plurality of DUTs, the optoelectronic probe card comprising:
an optical probe assembly that includes a plurality of lensed optical probes configured for non-contact optical communication with at least one optoelectronic device of the DUT; and
an electrical probe assembly that includes a plurality of electrical probes configured for electrical communication with the DUT via electrical contact between the plurality of electrical probes and a plurality of contact pads of the DUT.
A2. The optoelectronic probe card of paragraph A1, wherein each lensed optical probe of the plurality of lensed optical probes includes at least one of:
(i) a corresponding optical fiber of a plurality of optical fibers of the optical probe assembly;
(ii) a corresponding probe lens of a plurality of probe lenses of the optical probe assembly;
(iii) a corresponding waveguide of a plurality of waveguides of the optical probe assembly; and
(iv) a corresponding grating coupler of a plurality of grating couplers of the optical probe assembly.
A3. The optoelectronic probe card of any of paragraphs A1-A2, wherein the optical probe assembly is configured to at least one of:
(i) convey at least one optical test signal to the at least one optoelectronic device via a corresponding signal-emitting lensed optical probe of the plurality of lensed optical probes; and
(ii) receive at least one optical resultant signal from the at least one optoelectronic device via a corresponding signal-receiving lensed optical probe of the plurality of lensed optical probes.
A4. The optoelectronic probe card of paragraph A3, wherein the corresponding signal-emitting lensed optical probe differs from the corresponding signal-receiving lensed optical probe.
A5. The optoelectronic probe card of any of paragraphs A3-A4, wherein the corresponding signal-emitting lensed optical probe and the corresponding signal-receiving lensed optical probe are the same lensed optical probe of the plurality of lensed optical probes.
A6. The optoelectronic probe card of any of paragraphs A3-A5, wherein at least one of:
(i) the corresponding signal-emitting lensed optical probe is configured to emit the at least one optical test signal and to focus the at least one optical test signal on the at least one optoelectronic device; and
(ii) the corresponding signal-receiving lensed optical probe is configured to collect the at least one optical resultant signal emitted by the at least one optoelectronic device.
A7. The optoelectronic probe card of any of paragraphs A1-A6, wherein each lensed optical probe of the plurality of lensed optical probes is configured to optically couple with at least one of:
(i) an upper surface of the DUT that at least partially defines the at least one optoelectronic device; and
(ii) a sidewall surface of the DUT that at least partially defines the at least one optoelectronic device.
A8. The optoelectronic probe card of any of paragraphs A1-A7, wherein each lensed optical probe of the plurality of lensed optical probes defines at least one of:
(i) a fixed orientation relative to each other lensed optical probe of the plurality of lensed optical probes;
(ii) a predetermined orientation relative to each other lensed optical probe; and
(iii) an orientation relative to each other lensed optical probe that is based, at least in part, on a configuration of the at least one optoelectronic device.
A9. The optoelectronic probe card of any of paragraphs A1-A8, wherein the plurality of electrical probes includes at least one of:
(i) a plurality of resilient electrical probes;
(ii) a plurality of electrically conductive electrical probes; and
(iii) a plurality of resiliently biased electrical probes.
A10. The optoelectronic probe card of any of paragraphs A1-A9, wherein each electrical probe of the plurality of electrical probes is configured to directly contact a corresponding contact pad of the plurality of contact pads.
A11. The optoelectronic probe card of any of paragraphs A1-A10, wherein the electrical probe assembly is configured to at least one of:
(i) convey at least one electrical test signal to at least one signal-receiving contact pad of the plurality of contact pads via a corresponding signal-emitting electrical probe of the plurality of electrical probes; and
(ii) receive at least one electrical resultant signal from at least one signal-emitting contact pad of the plurality of contact pads via a corresponding signal-receiving electrical probe of the plurality of electrical probes.
A12. The optoelectronic probe card of paragraph A11, wherein the corresponding signal-emitting electrical probe differs from the corresponding signal-receiving electrical probe.
A13. The optoelectronic probe card of any of paragraphs A11-A12, wherein the corresponding signal-emitting electrical probe and the corresponding signal-receiving electrical probe are the same electrical probe of the plurality of electrical probes.
A14. The optoelectronic probe card of any of paragraphs A1-A13, wherein each electrical probe of the plurality of electrical probes defines at least one of:
(i) a fixed orientation relative to each other electrical probe of the plurality of electrical probes;
(ii) a predetermined orientation relative to each other electrical probe; and
(iii) an orientation relative to each other electrical probe that corresponds to a relative orientation of the plurality of contact pads.
A15. The optoelectronic probe card of any of paragraphs A1-A14, wherein the optical probe assembly and the electrical probe assembly are positioned, relative to one another, such that the plurality of lensed optical probes is positioned for non-contact optical communication with the at least one optoelectronic device when the plurality of electrical probes is positioned for electrical contact with the plurality of contact pads.
A16. The optoelectronic probe card of any of paragraphs A1-A15, wherein the electrical probe assembly includes an electrical probe card, and further wherein the plurality of electrical probes extends from the electrical probe card.
A17. The optoelectronic probe card of paragraph A16, wherein the electrical probe card defines an opening, or an aperture, and further wherein the optical probe assembly is positioned at least partially within the opening.
A18. The optoelectronic probe card of paragraph A17, wherein the optical probe assembly extends, via the opening, between a device substrate-opposed side of the electrical probe card and a device substrate-facing side of the electrical probe card.
A19. The optoelectronic probe card of any of paragraphs A17-A18, wherein the opening at least partially, or fully, surrounds the plurality of lensed optical probes.
A20. The optoelectronic probe card of any of paragraphs A16-A19, wherein the optical probe assembly is operatively attached to the electrical probe card such that the plurality of lensed optical probes and the plurality of electrical probes define a fixed, or at least substantially fixed, relative orientation therebetween.
A21. The optoelectronic probe card of any of paragraphs A1-A20, wherein the optoelectronic probe card includes a probe assembly actuator configured to selectively generate relative motion between the plurality of lensed optical probes and the plurality of electrical probes.
A22. The optoelectronic probe card of paragraph A21, wherein the probe assembly actuator is configured to operatively translate the plurality of lensed optical probes relative to the plurality of electrical probes.
A23. The optoelectronic probe card of any of paragraphs A21-A22, wherein the probe assembly actuator is configured to operatively translate the plurality of electrical probes relative to the plurality of lensed optical probes.
A24. The optoelectronic probe card of any of paragraphs A21-A23, wherein the probe assembly actuator operatively attaches the optical probe assembly and the electrical probe assembly to one another.
A25. The optoelectronic probe card of any of paragraphs A21-A24, wherein one of the optical probe assembly and the electrical probe assembly is operatively attached to a support structure and defines a fixed, or at least substantially fixed, orientation relative to the support structure, and further wherein the other of the optical probe assembly and the electrical probe assembly is operatively attached to the support structure via the probe assembly actuator.
A26. The optoelectronic probe card of any of paragraphs A21-A25, wherein the probe assembly actuator is configured to selectively generate the relative motion at least one of:
(i) in two dimensions;
(ii) in a motion plane that extends parallel, or at least substantially parallel, to an upper surface of the device substrate; and
(iii) in the motion plane that extends parallel, or at least substantially parallel, to an electrical contact plane within which the plurality of electrical probes contacts the plurality of contact pads.
A27. The optoelectronic probe card of paragraph A26, wherein the probe assembly actuator is configured to selectively generate the relative motion within a third dimension that extends perpendicular, or at least substantially perpendicular, to at least one of:
(i) the two dimensions; and
(ii) the motion plane.
A28. The optoelectronic probe card of any of paragraphs A1-A27, wherein the optoelectronic probe card further includes a card substrate, wherein the optical probe assembly is at least partially defined by the card substrate, and further wherein the electrical probe assembly is at least partially defined by the card substrate.
A29. The optoelectronic probe card of paragraph A28, wherein the plurality of lensed optical probes defines a fixed orientation relative to the card substrate, and further wherein the plurality of electrical probes defines a fixed orientation relative to the card substrate.
A30. The optoelectronic probe card of any of paragraphs A28-A29, wherein the plurality of lensed optical probes extends from the card substrate, and further wherein the plurality of electrical probes extends from the card substrate.
A31. The optoelectronic probe card of any of paragraphs A28-A30, wherein the plurality of lensed optical probes is operatively attached to the card substrate, and further wherein the plurality of electrical probes is operatively attached to the card substrate.
A32. The optoelectronic probe card of any of paragraphs A28-A31, wherein the plurality of lensed optical probes and the plurality of electrical probes define a fixed, or at least substantially fixed, relative orientation therebetween.
A33. The optoelectronic probe card of any of paragraphs A28-A32, wherein the optoelectronic probe card includes an/the plurality of optical fibers and an optical interface structure in optical communication with the plurality of optical fibers.
A34. The optoelectronic probe card of paragraph A33, wherein the optical interface structure includes a plurality of optical fiber receptacles, wherein each optical fiber receptacle of the plurality of optical fiber receptacles is configured to receive a corresponding optical fiber of the plurality of optical fibers.
A35. The optoelectronic probe card of paragraph A34, wherein the plurality of optical fiber receptacles includes a plurality of V-grooves at least partially defined within the card substrate.
A36. The optoelectronic probe card of any of paragraphs A33-A35, wherein the optical interface structure includes a plurality of fiber-interfaced grating couplers, wherein each fiber-interfaced grating coupler of the plurality of fiber-interfaced grating couplers is in optical communication with a corresponding optical fiber of the plurality of optical fibers, optionally wherein the plurality of fiber-interfaced grating couplers is at least partially, or even completely, defined on, or within, the card substrate.
A37. The optoelectronic probe card of any of paragraphs A33-A36, wherein the optoelectronic probe card includes a plurality of waveguides, wherein each waveguide of the plurality of waveguides is in optical communication with a corresponding optical fiber of the plurality of optical fibers via the optical interface structure, optionally wherein each waveguide of the plurality of waveguides is at least partially, or even completely, defined on, or within, the card substrate.
A38. The optoelectronic probe card of paragraph A37, wherein the optoelectronic probe card includes a plurality of lens-interfaced grating couplers and a/the plurality of probe lenses, wherein each waveguide is in optical communication with a corresponding probe lens of the plurality of probe lenses via a corresponding lens-interfaced grating coupler of the plurality of lens-interfaced grating couplers, optionally wherein the plurality of lens-interfaced grating couplers is at least partially, or even completely, defined on, or within, the card substrate.
A39. The optoelectronic probe card of any of paragraphs A28-A38, wherein the card substrate includes, or is, at least one of a semiconductor substrate and a printed circuit board substrate.
A40. The optoelectronic probe card of any of paragraphs A1-A39, wherein the optoelectronic probe card is configured for optical and electrical communication with a single, or only a single, DUT at a given time.
A41. The optoelectronic probe card of any of paragraphs A1-A40, wherein the optoelectronic probe card is configured for optical and electrical communication with a plurality of DUTs at a given time.
A42. The optoelectronic probe card of paragraph A41, wherein the optoelectronic probe card includes a plurality of optical probe assemblies and a corresponding plurality of electrical probe assemblies, wherein each optical probe assembly of the plurality of optical probe assemblies and each electrical probe assembly of the corresponding plurality of electrical probe assemblies is configured for electrical and optical communication with a corresponding DUT of the plurality of DUTs.
A43. The optoelectronic probe card of paragraph A42, wherein the plurality of electrical probe assemblies defines a fixed, or at least substantially fixed, relative orientation therebetween.
A44. The optoelectronic probe card of any of paragraphs A42-A43, wherein the plurality of optical probe assemblies defines a fixed, or at least substantially fixed, relative orientation therebetween.
A45. The optoelectronic probe card of any of paragraphs A42-A44, wherein the optoelectronic probe card includes a plurality of probe assembly actuators, wherein each probe assembly actuator of the plurality of probe assembly actuators is configured to selectively generate relative motion between a corresponding optical probe assembly of the plurality of optical probe assemblies and a corresponding electrical probe assembly of the plurality of electrical probe assemblies.
B1. An optoelectronic tester for optically and electrically testing a device under test (DUT) on a device substrate that includes a plurality of DUTs, the optoelectronic tester comprising:
a chuck that defines a support surface configured to support the device substrate;
the optoelectronic probe card of any of paragraphs A1-A45;
an optical signal generation and analysis assembly configured to at least one of provide an optical test signal to the DUT via the optical probe assembly of the optoelectronic probe card and receive an optical resultant signal from the DUT via the optical probe assembly; and
an electrical signal generation and analysis assembly configured to at least one of provide an electrical test signal to the DUT via the electrical probe assembly of the optoelectronic probe card and receive an electrical resultant signal from the DUT via the electrical probe assembly.
B2. The optoelectronic tester of paragraph B1, wherein the optoelectronic tester further includes a chuck stage configured to at least one of translate the support surface relative to the optoelectronic probe card and rotate the support surface relative to the optoelectronic probe card.
B3. The optoelectronic tester of any of paragraphs B1-B2, wherein the optoelectronic tester further includes a controller programmed to control the operation of the optoelectronic tester according to any suitable step and/or steps of any of the methods of any of paragraphs C1-E9.
C1. A method of testing a device under test (DUT), which is on a device substrate that includes a plurality of DUTs, utilizing an optoelectronic probe card, wherein the optoelectronic probe card includes an optical probe assembly that includes a plurality of lensed optical probes, an electrical probe assembly that includes a plurality of electrical probes, the method comprising:
aligning the plurality of electrical probes with a plurality of corresponding contact pads of the DUT; and
aligning the plurality of lensed optical probes with at least one optoelectronic device of the DUT.
D1. The method of paragraph C1, wherein:
the plurality of lensed optical probes and the plurality of electrical probes define a fixed, or a predetermined, relative orientation therebetween;
the aligning the plurality of electrical probes includes, or instead is, actively aligning the plurality of electrical probes with a plurality of corresponding contact pads of the DUT; and
the aligning the plurality of lensed optical probes includes, or instead is, passively aligning the plurality of lensed optical probes with at least one optoelectronic device of the DUT.
D2. The method of paragraph D1, wherein the actively aligning the plurality of electrical probes includes at least one of:
(i) moving the plurality of electrical probes relative to the plurality of corresponding contact pads; and
(ii) moving the plurality of corresponding contact pads relative to the plurality of electrical probes.
D3. The method of any of paragraphs D1-D2, wherein the actively aligning the plurality of electrical probes includes electrically contacting the plurality of electrical probes to the plurality of corresponding contact pads.
D4. The method of any of paragraphs D1-D3, wherein the actively aligning the plurality of electrical probes includes optically viewing at least one of the plurality of electrical probes and the plurality of corresponding contact pads.
D5. The method of any of paragraphs D1-D4, wherein the passively aligning the plurality of lensed optical probes is responsive to the actively aligning the plurality of electrical probes.
D6. The method of any of paragraphs D1-D5, wherein the method includes maintaining a fixed relative orientation between the plurality of electrical probes and the plurality of lensed optical probes during the actively aligning the plurality of electrical probes and also during the passively aligning the plurality of lensed optical probes.
E1. The method of paragraph C1, wherein:
the plurality of lensed optical probes and the plurality of electrical probes define a fixed, or a predetermined, relative orientation therebetween;
the aligning the plurality of lensed optical probes includes, or instead is, actively aligning the plurality of lensed optical probes with at least one optoelectronic device of the DUT; and
the aligning the plurality of electrical probes includes, or instead is, passively aligning the plurality of electrical probes with a plurality of corresponding contact pads of the DUT.
E2. The method of paragraph E1, wherein the actively aligning the plurality of lensed optical probes includes at least one of:
(i) moving the plurality of lensed optical probes relative to the at least one optoelectronic device; and
(ii) moving the at least one optoelectronic device relative to the plurality of lensed optical probes.
E3. The method of any of paragraphs E1-E2, wherein the actively aligning the plurality of lensed optical probes includes establishing a relative orientation, between the plurality of lensed optical probes and the at least one optoelectronic device, that provides at least a threshold optical coupling efficiency between the plurality of lensed optical probes and the at least one optoelectronic device.
E4. The method of paragraph E3, wherein the establishing the relative orientation includes establishing the optical coupling between the plurality of lensed optical probes and the at least one optoelectronic device.
E5. The method of any of paragraphs E3-E4, wherein the establishing the relative orientation includes scanning the plurality of lensed optical probes and the at least one optoelectronic device relative to one another in two, at least two, or three dimensions to determine the relative orientation that provides at least the threshold optical coupling efficiency.
E6. The method of any of paragraphs E1-E5, wherein the actively aligning the plurality of lensed optical probes includes actively aligning the plurality of lensed optical probes with the at least one optoelectronic device while the plurality of electrical probes is at least one of:
(i) spaced-apart from the plurality of corresponding contact pads; and
(ii) out of contact with the plurality of corresponding contact pads.
E7. The method of any of paragraphs E1-E6, wherein the actively aligning the plurality of lensed optical probes includes optically viewing at least one of the plurality of lensed probes and the at least one optoelectronic device.
E8. The method of any of paragraphs E1-E7, wherein the passively aligning the plurality of electrical probes is responsive to the actively aligning the plurality of lensed optical probes.
E9. The method of any of paragraphs E1-E8, wherein the method includes maintaining a fixed relative orientation between the plurality of electrical probes and the plurality of lensed optical probes during the actively aligning the plurality of lensed optical probes and also during the passively aligning the plurality of electrical probes.
E10. The method of any of paragraphs E1-E9, wherein, subsequent to the actively aligning the plurality of lensed optical probes, the method further includes electrically contacting the plurality of electrical probes with the plurality of corresponding contact pads.
E11. The method of paragraph E10, wherein the actively aligning the plurality of lensed optical probes includes establishing an aligned relative orientation between the plurality of lensed optical probes and the at least one optoelectronic device at which a corresponding optical axis of each lensed optical probe of the plurality of lensed optical probes is incident upon a corresponding region of the at least one optoelectronic device and defines a corresponding aligned optical path length between each lensed optical probe and the corresponding region of the at least one optoelectronic device.
E12. The method of paragraph E11, wherein the electrically contacting includes establishing a contacted relative orientation between the plurality of lensed optical probes and the at least one optoelectronic device at which:
(i) the corresponding optical axis of each lensed optical probe is incident upon the corresponding region of the at least one optoelectronic device;
(ii) the corresponding optical axis defines a corresponding contacted optical path length that is greater than zero and less than the corresponding aligned optical path length; and
(iii) the plurality of electrical probes is in electrical contact with the plurality of corresponding contact pads.
E13. The method of paragraph E12, wherein the method further includes calculating the contacted relative orientation based, at least in part, on the aligned relative orientation and a/the fixed relative orientation between the plurality of lensed optical probes and the plurality of electrical probes.
F1. The method of paragraph C1, wherein:
the aligning the plurality of electrical probes includes, or instead is, actively aligning the plurality of electrical probes with a plurality of corresponding contact pads of the DUT; and
the aligning the plurality of lensed optical probes includes, or instead is, actively aligning the plurality of lensed optical probes with at least one optoelectronic device of the DUT.
F2. The method of paragraph F1, wherein the actively aligning the plurality of electrical probes includes electrically contacting the plurality of electrical probes to the plurality of corresponding contact pads.
F3. The method of any of paragraphs F1-F2, wherein the actively aligning the plurality of electrical probes includes optically viewing at least one of the plurality of electrical probes and the plurality of corresponding contact pads.
F4. The method of any of paragraphs F1-F3, wherein the actively aligning the plurality of electrical probes is performed prior to the actively aligning the plurality of lensed optical probes.
F5. The method of any of paragraphs F1-F4, wherein the actively aligning the plurality of electrical probes includes at least one of:
(i) moving the plurality of corresponding contact pads relative to the plurality of electrical probes, optionally utilizing a chuck stage of a chuck that defines a support surface that supports the device substrate; and
(ii) moving the plurality of corresponding contact pads relative to the plurality of lensed optical probes, optionally utilizing the chuck stage.
F6. The method of any of paragraphs F1-F5, wherein the actively aligning the plurality of lensed optical probes includes establishing a relative orientation, between the plurality of lensed optical probes and the at least one optoelectronic device, that provides at least a threshold optical coupling efficiency between the plurality of lensed optical probes and the at least one optoelectronic device.
F7. The method of paragraph F6, wherein the establishing the relative orientation includes establishing the optical coupling between the plurality of lensed optical probes and the at least one optoelectronic device.
F8. The method of any of paragraphs F6-F7, wherein the establishing the relative orientation includes scanning the plurality of lensed optical probes and the at least one optoelectronic device relative to one another in two, at least two, or three dimensions to determine the relative orientation that provides at least the threshold optical coupling efficiency.
F9. The method of any of paragraphs F1-F8, wherein the actively aligning the plurality of lensed optical probes includes at least one of:
(i) moving the plurality of lensed optical probes relative to the at least one optoelectronic device, optionally utilizing a probe assembly actuator; and
(ii) moving the plurality of lensed optical probes relative to the plurality of electrical probes, optionally utilizing the probe assembly actuator.
G1. The method of any of paragraphs C1-F9, wherein the method further includes simultaneously optically testing the DUT and electrically testing the DUT.
G2. The method of paragraph G1, wherein the optically testing includes at least one of:
(i) providing at least one optical test signal to the DUT utilizing at least one lensed optical probe of the plurality of lensed optical probes; and
(ii) receiving at least one optical resultant signal from the DUT utilizing at least one lensed optical probe of the plurality of lensed optical probes.
G3. The method of any of paragraphs G1-G2, wherein the electrically testing includes at least one of:
(i) providing at least one electrical test signal to the DUT utilizing at least one electrical probe of the plurality of electrical probes; and
(ii) receiving at least one electrical resultant signal from the DUT utilizing at least one electrical probe of the plurality of electrical probes.
G4. The method of any of paragraphs C1-G3, wherein the optoelectronic probe card includes any suitable structure, function, and/or feature of any of the optoelectronic probe cards of any of paragraphs A1-A45.
G5. The method of any of paragraphs C1-G4, wherein the method is performed utilizing any suitable structure, function, and/or feature of any of the optoelectronic testers of any of paragraphs B1-B3.
H1. Non-transitory computer-readable storage media including computer-executable instructions that, when executed, direct an optoelectronic tester to perform any suitable step and/or steps of any of the methods of any of paragraphs C1-G5.

### INDUSTRIAL APPLICABILITY

The optoelectronic probe cards, optoelectronic testers, and methods disclosed herein are applicable to the semiconductor manufacturing and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. An optoelectronic probe card for optical and electrical communication with a device under test (DUT) on a device substrate that includes a plurality of DUTs, the optoelectronic probe card comprising:
an optical probe assembly that includes a plurality of lensed optical probes configured for non-contact optical communication with at least one optoelectronic device of the DUT, wherein each lensed optical probe of the plurality of lensed optical probes defines a fixed orientation relative to each other lensed optical probe of the plurality of lensed optical probes; and
an electrical probe assembly that includes a plurality of electrical probes configured for electrical communication with the DUT via electrical contact between the plurality of electrical probes and a plurality of contact pads of the DUT, wherein each electrical probe of the plurality of electrical probes defines a fixed orientation relative to each other electrical probe of the plurality of electrical probes.

2. The optoelectronic probe card of claim 1, wherein the optical probe assembly and the electrical probe assembly are positioned, relative to one another, such that the plurality of lensed optical probes is positioned for non-contact optical communication with the at least one optoelectronic device when the plurality of electrical probes is positioned for electrical contact with the plurality of contact pads.

3. The optoelectronic probe card of claim 1, wherein the electrical probe assembly includes an electrical probe card, wherein the plurality of electrical probes extends from the electrical probe card, wherein the electrical probe card defines an opening, and further wherein the optical probe assembly is positioned at least partially within the opening.

4. The optoelectronic probe card of claim 3, wherein the optical probe assembly extends, via the opening, between a device substrate-opposed side of the electrical probe card and a device substrate-facing side of the electrical probe card.

5. The optoelectronic probe card of claim 3, wherein the optical probe assembly is operatively attached to the electrical probe card such that the plurality of lensed optical probes and the plurality of electrical probes define an at least substantially fixed relative orientation therebetween.

6. The optoelectronic probe card of claim 1, wherein the optoelectronic probe card includes a probe assembly actuator configured to selectively generate relative motion between the plurality of lensed optical probes and the plurality of electrical probes.

7. The optoelectronic probe card of claim 6, wherein the probe assembly actuator operatively attaches the optical probe assembly and the electrical probe assembly to one another.

8. The optoelectronic probe card of claim 6, wherein one of the optical probe assembly and the electrical probe assembly is operatively attached to a support structure and defines an at least substantially fixed orientation relative to the support structure, and further wherein the other of the optical probe assembly and the electrical probe assembly is operatively attached to the support structure via the probe assembly actuator.

9. The optoelectronic probe card of claim 6, wherein the probe assembly actuator is configured to selectively generate the relative motion in two dimensions.

10. The optoelectronic probe card of claim 9, wherein the probe assembly actuator is configured to selectively generate the relative motion within a third dimension that extends at least substantially perpendicular to the two dimensions.

11. The optoelectronic probe card of claim 1, wherein the optoelectronic probe card further includes a card substrate, wherein the optical probe assembly is at least partially defined by the card substrate, wherein the electrical probe assembly is at least partially defined by the card substrate, wherein the plurality of lensed optical probes defines a fixed orientation relative to the card substrate, and further wherein the plurality of electrical probes defines a fixed orientation relative to the card substrate.

12. The optoelectronic probe card of claim 11, wherein the plurality of lensed optical probes extends from the card substrate, and further wherein the plurality of electrical probes extends from the card substrate.

13. The optoelectronic probe card of claim 11, wherein the card substrate is at least one of a semiconductor substrate and a printed circuit board substrate.

14. The optoelectronic probe card of claim 1, wherein the optoelectronic probe card is configured for optical and electrical communication with a plurality of DUTs at a given time, wherein the optoelectronic probe card includes a plurality of optical probe assemblies and a corresponding plurality of electrical probe assemblies, wherein each optical probe assembly of the plurality of optical probe assemblies and each electrical probe assembly of the corresponding plurality of electrical probe assemblies is configured for electrical and optical communication with a corresponding DUT of the plurality of DUTs.

15. The optoelectronic probe card of claim 14, wherein the plurality of electrical probe assemblies defines an at least substantially fixed relative orientation therebetween.

16. The optoelectronic probe card of claim 14, wherein the optoelectronic probe card includes a plurality of probe assembly actuators, wherein each probe assembly actuator of the plurality of probe assembly actuators is configured to selectively generate relative motion between a corresponding optical probe assembly of the plurality of optical probe assemblies and a corresponding electrical probe assembly of the plurality of electrical probe assemblies.

17. An optoelectronic tester for optically and electrically testing a device under test (DUT) on a device substrate that includes a plurality of DUTs, the optoelectronic tester comprising:
a chuck that defines a support surface configured to support the device substrate;
the optoelectronic probe card of claim 1;
an optical signal generation and analysis assembly configured to at least one of provide an optical test signal to the DUT via the optical probe assembly of the optoelectronic probe card and receive an optical resultant signal from the DUT via the optical probe assembly; and
an electrical signal generation and analysis assembly configured to at least one of provide an electrical test signal to the DUT via the electrical probe assembly of the optoelectronic probe card and receive an electrical resultant signal from the DUT via the electrical probe assembly.

18. A method of testing a device under test (DUT), which is on a device substrate that includes a plurality of DUTs, utilizing an optoelectronic probe card, wherein the optoelectronic probe card includes an optical probe assembly that includes a plurality of lensed optical probes and an electrical probe assembly that includes a plurality of electrical probes, and further wherein the plurality of lensed optical probes and the plurality of electrical probes define a fixed relative orientation therebetween, the method comprising:
actively aligning the plurality of electrical probes with a plurality of corresponding contact pads of the DUT; and
passively aligning the plurality of lensed optical probes with at least one optoelectronic device of the DUT.

19. A method of testing a device under test (DUT), which is on a device substrate that includes a plurality of DUTs, utilizing an optoelectronic probe card, wherein the optoelectronic probe card includes an optical probe assembly that includes a plurality of lensed optical probes and an electrical probe assembly that includes a plurality of electrical probes, and further wherein the plurality of lensed optical probes and the plurality of electrical probes define a fixed relative orientation therebetween, the method comprising:
actively aligning the plurality of lensed optical probes with at least one optoelectronic device of the DUT; and
passively aligning the plurality of electrical probes with a plurality of corresponding contact pads of the DUT.

20. A method of testing a device under test (DUT), which is on a device substrate that includes a plurality of DUTs, utilizing an optoelectronic probe card, wherein the optoelectronic probe card includes an optical probe assembly that includes a plurality of lensed optical probes, and an electrical probe assembly that includes a plurality of electrical probes, the method comprising:
actively aligning the plurality of electrical probes with a plurality of corresponding contact pads of the DUT; and
actively aligning the plurality of lensed optical probes with at least one optoelectronic device of the DUT.
